(19) United States
(12) Patent Application Publication
(10) Pub. No.: US 2009/0208725 A1
(43) Pub. Date: Aug. 20, 2009

(54) LAYER TRANSFER FOR LARGE AREA INORGANIC FOILS

(76) Inventors: Robert J. Bailey, Scotts Valley, CA (US); William A. Sanders, Palo Alto, CA (US); Ronald J. Mosso, Fremont, CA (US); Henry Hieslmair, San Francisco, CA (US); Julio E. Morris, Fremont, CA (US); Martin E. Mogaard, Scotts Valley, CA (US); Jacob A. Hernandez, Morgan Hill, CA (US)

Correspondence Address: DARDI & ASSOCIATES, PLLC, 220 S. 6TH ST., SUITE 2000, U.S. BANK PLAZA, MINNEAPOLIS, MN, 55402, US

(21) Appl. No.: 12/359,019

(22) Filed: Jan. 23, 2009

Related U.S. Application Data
(60) Provisional application No. 61/062,399, filed on Jan. 25, 2008.

(51) Int. Cl. B32B 5/18; B05D 1/12; C23C 16/00; B29C 65/78

(52) U.S. Cl. 428/312.2; 427/203; 427/255.28; 156/538; 156/344

(57) ABSTRACT

Layer transfer approaches are described to take advantage of large area, thin inorganic foils formed onto a porous release layer. In particular, since the inorganic foils can be formed from ceramics and/or crystalline materials that do not bend a large amount, approaches are described to provide for gradual pulling along an edge to separate the foil from a holding surface along a curved surface designed to not excessively bend the foil such that the foil is not substantially damaged in the transfer process. Apparatuses are described to perform the transfer with a rocking motion or with a rotating cylindrical surface. Furthermore, stabilization of porous release layers can improve the qualities of resulting inorganic foils formed on the release layer. In particular, flame treatments can provide improved release layer properties, and the deposition of an interpenetrating stabilization composition can be deposited using CVD to stabilize a porous layer.

### CROSS REFERENCE TO RELATED APPLICATIONS

This application claims priority to copending U.S. provisional patent application Ser. No. 61/062,399, filed on Jan. 25, 2008 to Mosso et al., entitled “Layer Transfer for Large Area Inorganic Foils,” incorporated herein by reference.

### FIELD OF THE INVENTION

This application relates to the handling and transfer of thin large area inorganic foils, generally from an initial support structure to another support structure. Suitable inorganic foils can comprise a semiconductor material, which can be useful, for example, for photovoltaic applications.

### BACKGROUND OF THE INVENTION

Semiconductor materials are widely used commercial materials for the production of a great many electronic devices. Silicon in its elemental form is a commonly used semiconductor that is a fundamental material for integrated circuit production. Single crystal or large crystallite silicon can be grown in cylindrical ingots that are subsequently cut into wafers. Polycrystalline silicon and amorphous silicon can be used effectively for appropriate applications. Suitable doping of the silicon can be used to alter the semiconducting properties as desired.

Various technologies are available for the formation of photovoltaic cells, e.g., solar cells, in which a semiconducting material functions as a photoconductor. A majority of commercial photovoltaic cells are based on silicon. With non-renewable energy sources continuing to be less desirable due to environmental and cost concerns, there is continuing interest in alternative energy sources, especially renewable energy sources. Increased commercialization of renewable energy sources relies on increasing cost effectiveness through lower costs per energy unit, which can be achieved through improved efficiency of the energy source and/or through cost reduction for materials and processing. Thus, for a photovoltaic cell, commercial advantages can result from increased energy conversion efficiency for a given light fluence and/or from lower cost of producing a cell.

### SUMMARY OF THE INVENTION

In a first aspect, the invention pertains to a method for the deposition of an inorganic foil onto a release layer in which the method comprises depositing a porous release layer, passing a combustion flame over the porous release layer and depositing an inorganic foil over the flame treated release layer. The step of depositing a porous particulate release layer generally is performed from a product flow generated by a reaction driven by a light beam wherein a reactant flow originates from an inlet. In some embodiments, the resulting porous particulate release layer has a density from about 5 percent to about 25 percent of the density of the corresponding fully densified material. The step of passing a combustion flame over the porous particulate release layer can be performed at least once to decrease the average thickness of the porous particulate layer by at least a factor of two relative to the original average thickness of the release layer and to reduce the surface roughness as observed in a scanning electron micrograph. The step of depositing an inorganic foil onto the porous particulate release layer generally is performed after passing the combustion flame over the release layer. The inorganic foil can have a thickness of no more than about 200 microns, and the release layer can be fractured to remove a substantially intact foil.

In further aspects, the invention pertains to a structure comprising an inorganic substrate, a release layer and an inorganic foil on the release layer. In some embodiments, the release layer comprises an inorganic composition, and has an average thickness from about 10 microns to about 200 microns and a density from about 20 percent to about 60 percent of the density of the corresponding fully densified composition. The release layer can comprise a porous particulate layer with an interspersed dense inorganic joining composition that has a different chemical composition from the inorganic foil. The inorganic foil can comprise a composition with a melting or flow temperature less than the melting or flow temperature of the inorganic composition of the release layer and having a thickness from about 10 microns to about 100 microns.

In other aspects, the invention pertains to a method for the formation of a release layer in which the method comprises a step of depositing an inorganic composition using chemical vapor deposition onto a porous particulate layer having a thickness from about 10 microns to about 250 microns. The chemical vapor deposition generally deposits a quantity of inorganic composition corresponding to an equivalent amount of a fully dense composition in a layer with an average thickness from about 0.25 microns to about 10 microns. In some embodiments, at least a majority of the composition deposited with chemical vapor deposition is embedded within the porous particulate layer.

In additional aspects, the invention pertains to an apparatus for transferring a thin inorganic foil from a bound position on a substrate to a receiving surface. The apparatus comprises a transport element comprising a curved adhering receiving surface, a substrate support and a transport system. The transport system generally comprises an actuator and a shifting element. The actuator has a positioning motor that moves the curved receiving surface towards or away from a substrate supported by the substrate support. In some embodiments, the shifting element provides a motion to lift an edge of the foil in contact with the receiving surface to propagate a point of contact between the receiving surface and the foil along the respective surfaces.

Furthermore, the invention pertains to a method for separating an inorganic foil from a substrate wherein the inorganic foil has a thickness of no more than 200 microns. Generally, the method comprises shifting a curved adhering receiving surface along the surface of the foil to peel the foil from a substrate along a line segment that propagates as the point of contact between the receiving surface and the foil shift along the surface. The foil is initially releaseably bound to the substrate, and the foil becomes bound to the receiving surface at least temporarily.

### BRIEF DESCRIPTION OF THE DRAWINGS

FIG. 1 is a schematic sectional view of a thin organic foil on a release layer supported on a substrate.

FIG. 2 is a schematic sectional view of the foil separated from the substrate with remnants of the release layer on the surface of the foil.

FIG. 3 is a schematic sectional view of the foil of FIG. 1 transferred to a receiving surface on receiving element.

FIG. 4 is a schematic sectional view of the foil of FIG. 1 associated with a receiving surface with remnants of the release layer located between the foil and the receiving surface.

FIG. 5 is a schematic view of a release layer formed with alternating layers of a porous particulate materials and an interpenetrating joining composition.

FIG. 6 is a perspective view of an apparatus for performing light reactive deposition LRD™) and/or scanning sub-atmospheric pressure CVD (SSAP-CVD) deposition.

FIG. 7 is a schematic view of an embodiment of a reactant delivery system.

FIG. 8 is schematic perspective view of an embodiment of a layer transfer apparatus based on a rocking release mechanism in which a substrate and receiving element are displaced for view from their operational positions and in which the wall of the enclosure are shown as transparent to allow for visualization of the internal elements.

FIG. 9 is a schematic view of an alternative embodiment of a layer transfer apparatus in which a transfer roller is used to supply a temporary receiving surface for peeling of the foil away form the substrate.

FIG. 10 is a schematic side view of the roller of FIG. 9 in which the foil has been partially transferred form an initial substrate to a receiving surface.

FIG. 11 is a scanning electron micrograph (SEM) cross sectional image showing a multilayer release layer deposited with a combination of LRD™ deposition and SSAP-CVD in alternating steps with three layers of each.

FIG. 12 is an SEM top image of a tile deposited with the multilayer structure of FIG. 11.

FIG. 13 is an SEM cross sectional image taken with a scanning electron micrograph of an as-deposited porous, particulate release layer.

FIG. 14 is an SEM cross sectional image of a layer deposited as shown in FIG. 13 following one pass with an oxyacetylene torch.

FIG. 15 is an SEM cross sectional image of a layer deposited as shown in FIG. 13 following two passes with an oxyacetylene torch.

FIG. 16 is an SEM cross sectional image of a layer deposited as shown in FIG. 13 following three passes with an oxyacetylene torch.

FIG. 17 is an SEM cross sectional image at higher magnification of a porous release layer after four passes through an oxyacetylene torch.

FIG. 18 is an SEM top image of a porous particulate release layer as deposited by LRD™ deposition without any flame treatment.

FIG. 19 is an SEM top image of a porous release layer after four passages through an oxyacetylene flame.

FIG. 20 is an SEM cross sectional image of a dense scanning sub-atmospheric pressure SiO₂ layer deposited onto a porous release layer, as deposited by LRD™.

FIG. 21 is an SEM cross sectional image of a dense scanning sub-atmospheric pressure SiO₂ layer deposited onto a flame densified porous release layer.

FIG. 22 is a high resolution SEM cross sectional image of the interface of a CVD deposition onto a porous release layer without flame densification.

FIG. 23 is a high resolution SEM cross sectional image of the interface of a CVD deposition onto a flame densified porous release layer.

FIG. 24 is a SEM cross sectional image of a SiO₂ foil in contact with a porous release layer without flame densification.

FIG. 25 is a SEM cross sectional image of a SiO₂ foil in contact with a flame densified porous release layer.

### DETAILED DESCRIPTION OF THE INVENTION

The ability to form a thin inorganic foil on a release layer creates new issues with respect to material handling that involve the transfer of the foil away from the release layer and generally to placement in association with another surface. Furthermore, the properties of the release layer can be engineered to improve the properties of the foil while maintaining the ability to separate an intact foil from the release layer. The modification of the release layer can comprise the densification of a porous particulate release layer using a flame and/or through the deposition of a dense inorganic stabilization composition onto the porous layer to increase the density of the release layer. The transfer process can be made efficient and robust without damaging delicate foils, which can have desirable high quality properties. The process can be successfully used for handling large area silicon foils with thickness in some embodiments of no more than about 100 microns. The foils can comprise one or a plurality of layers. In some embodiments, multiple layer transfers can be performed to present the foil onto an ultimate substrate for further processing into products. Large area sheets can be processed into photovoltaic cells as well as display circuits and other large area semiconductor devices.

An appropriately engineered release layer provides a reasonable surface for depositing the foil using reactive deposition while maintaining the ability to selectively fracture to allow the separation of the foil without significant damage to the foil. Thus, it can be desirable to stabilize the release layer without reaching the point where the release layer does not fracture with an appropriate application of force. In general, the foil is peeled from the substrate to tear the release layer or to release other binding forces. If the foil is placed onto a final receiving surface, this transfer can be performed though the gentle bending of the receiving surface and with a rocking motion of the curved receiving surface to tear or peel the foil away from the substrate. This tearing motion keeps the forces to separate the foil at reasonable values such that the foil can be separated from a reasonably stable release layer or other temporary receiving surface without significantly damaging the foil. Furthermore, since the separation of the foil through the lifting along an edge has linearly scaling force, the area of the foil does not alter ability to separate the foil so that large area foils can be similarly handled. In general, the degree of appropriate bending depends on the flexibility of the foil, and the strength of the release layer or other binding forces should account for any limitations imposed due to constraint on the flexibility of the foil. If the foil is sufficiently flexible, a rotating temporary receiving surface can transport the foil directly to another receiving surface, such as a permanent receiving surface.

Deposition techniques have been developed that make it possible to form inorganic films with a selected composition on an appropriate release layer such that relatively modest mechanical forces can be used to separate an inorganic foil from the underlying substrate at the release layer. The processing of the inorganic foil into an ultimate product can involve, for example, the manipulation of the foil with respect to modifying at least a portion of the foil, adding additional compositions, such as patterns of compositions, along the foil surface, and/or attaching the foil onto another structure. Generally, the formation of a product from the foil comprises the separation of the foil from the release layer through a transfer process. The inorganic foil can be supported during manipulations to reduce the likelihood of damaging of the foil. To process both surfaces of the foil and/or to place the processed foil onto an ultimate receiving surface, the foil can be transferred a plurality of times.

The release layer can be a porous inorganic structure which generally has a high sintering temperature so that the foil can be deposited onto the release layer using a reactive deposition approach without densifying or otherwise modifying the release layer in undesirable ways. Due to the thinness of the foils, the foil or portion thereof can be somewhat resilient so that the foil is less likely to crack while the foil is separated from the release layer. This can be a significant issue for ceramic foils as well as crystalline materials, such as a polycrystalline elemental silicon foil. In some embodiments, the foil can be induced to have a gentle bend without damaging the foil. The use of a porous release layer provides an effective surface for the deposition of the foil with desired properties while simultaneously allowing the transfer of the foil from the deposition substrate based on reasonable separation forces generally without further action on the release layer. A receiving surface can provide the appropriate separating forces based on adhesive, electrostatic forces, suction forces, or the like or a combination thereof. The forces can be effective to lift the foil from an originating surface for transfer to a receiving surface. If the forces adhering the foil to the receiving layer are appropriately reversible, multiple layer transfers can be performed to place the foil on its ultimate receiving surface. While generally, the foils can comprise a selected inorganic composition, there is particular interest in the transfer of silicon foils, such as polycrystalline silicon foils, which may or may not be doped.

In contrast with the present approaches, small area silicon sheets have been formed from ingots following the formation of a cleave plane. The cleave plane is formed using ion implantation or the like. Energy is propagated along the cleave plan to separate the surface layer. The use of a cleave plan is described further in U.S. Pat. No. 7,166,520 to Henley, entitled “Thin Handle Substrate for Fabricating Devices Using One or More Films Provided by a Layer Transfer Process,” incorporated herein by reference. The approaches described herein do not involve a cleave plane or similar structure and different methods are used to perform the layer transfer.

In general, any appropriate method can be used to form the initial inorganic film or foil, in association with a release layer. In particular, thin inorganic foils can be prepared on a release layer using reactive deposition approaches. The foils can be deposited, for example, using light reactive deposition (LRD™) or with chemical vapor deposition (CVD), e.g., scanning sub-atmospheric pressure chemical vapor deposition or atmospheric pressure CVD. Scanning reactive deposition approaches can effectively deposit inorganic materials at a significant rate.

LRD™ is a directed flow deposition process in which the reactive flow passes through a light beam that drives the reaction to form a product flow that is directed toward a substrate. Light reactive flow processes, such as light reactive deposition, feature a flowing reactive stream from a chamber inlet that intersects a light beam at a light reaction zone to form a product stream downstream from a light reaction zone. The light beam is oriented to not strike the substrate. In general, the product flow and substrate are moved relative to each other to scan the depositing product across the substrate surface. The intense light beam heats the reactants at a very rapid rate. While a laser beam, such as a beam from a CO₂ infrared laser, is a convenient energy source, other intense light sources can be used in LRD™. In LRD™, the reaction conditions and deposition parameters can be selected to change the nature of the coating with respect to density, porosity and the like. LRD™ onto a release layer is described generally in U.S. Pat. No. 6,788,866 to Bryan, entitled “Layer Material and Planar Optical Devices,” incorporated herein by reference as well as in published U.S. patent application 2007/0212510A to Hieslmair et al., entitled “Thin Silicon or Germanium Sheets and Photovoltaics Formed From Thin Sheets,” incorporated herein by reference.

CVD is a general term to describe the decomposition or other reaction of a precursor gas, e.g., silanes, at the surface of a substrate. CVD can also be enhanced with plasma or other energy source. CVD deposition can be well controlled to yield a uniform thin film at a relatively rapid deposition rate when performed in scanning mode. In particular, a directed reactant flow CVD has been developed with scanning of the deposition across a substrate surface in an enclosure at a pressure lower than the ambient pressure. Atmospheric pressure CVD can also be used to deposit thicker layers at reasonable rates. For silicon films, CVD can be performed on a substrate at or near atmospheric pressure at high temperatures ranging from 600° C. to 1200° C. The substrate holder needs to be appropriately designed for use at high temperatures. CVD deposition onto a porous release layer is described further in published PCT patent application WO 2008/156631 to Hieslmair et al., entitled “Reactive Flow Deposition and Synthesis of Inorganic Foils,” incorporated herein by reference.

LRD™ can also be used to form the release layer. Specifically, LRD™ can be used to form a layer with a selected composition and an appropriate porosity such that the porous layer can function as a release layer. The resulting porous layer generally comprises partially fused particles having a desired significant degree of porosity, which in some embodiments can be referred to as a porous particulate layer since primary particles may be visible in micrographs within the fused structure. In alternative embodiments, the release layer can be formed from a dispersion of particles, such as uniform submicron particles. The particle dispersion can be coated onto a substrate to form the release layer onto which a layer is formed using reactive deposition that results in the foil formation.

A porous release layer can be stabilized to form a better surface for the deposition of the foil. An initially formed porous inorganic structure may be too mechanically unstable to provide for processing of the foil without undesirable de-lamination from an underlying substrate and the surface may be too porous such that the deposited foil may interpenetrate into the release layer after deposition in an undesirable way that complicates further processing. In particular, an initially formed release layer can be subjected to heating in a flame to partially densify the layer and to modify the surface properties of the layer. The flame heating can be effective to form a flatter surface for foil deposition, reduce the incidence of undesired de-lamination of the foil from the underlying substrate prior to a separation step and to decrease the porosity of the surface. The flame heating also reduces the overall thickness and corresponding porosity of the release layer, which can be controlled such that the final release layer is sufficiently weak that it can be fractured to remove a substantially intact foil. The flame processing can be performed on an initially formed layer deposited with LRD™ or with a particle dispersion that is coated onto the substrate.

In additional or alternative embodiments, a dense deposition can be performed to deposit a stabilization composition within the porous particulate layer. For example, the stabilization composition can be deposited using scanning CVD, either at atmospheric pressures or sub-atmospheric. The deposition of a porous, particulate layer and a stabilization compound can be alternated to form a stabile release layer with the CVD deposited material essentially permeating the structure to form a stabile release layer that remains sufficiently mechanically weak that can be fractured to release a substantially intact inorganic foil. The amount of stabilization composition can be selected such that at least a majority of the composition is embedded within the porous structure.

In general, to form a foil the over-layers can comprise a selected composition, and the over-layers can have selected properties based on the intended use of the resulting structure. In some embodiments, at least one of the over-layers is an elemental silicon layer, which may or may not be doped. The elemental silicon layer can be subsequently applied in various semiconductor applications. With the ability to separate an overcoat structure from the underlying substrate, the large area and thin elemental silicon and/or germanium foils can be formed as well as other selected foils. The foils can comprise a plurality of distinct layers. In addition, a foil can be further processed while still associated with the release layer. The separated foils can be processed into desired devices, such as photovoltaic devices or displays. If a plurality of over-layers is deposited on the release layer, additional processing of the layers, such as a heat treatment, can be performed between deposition steps and/or after the deposition of the plurality of layers is completed.

For some applications, it is desirable to separate a thin silicon film into a thin foil of silicon that can then be subjected to further processing. It has been found that the silicon film can be successfully formed onto a porous release layer and subjected to zone melt recrystallization while still associated with the release layer. Upon the fracturing of the porous release layer, the thin silicon foil or other inorganic foil can become a free standing structure. However, the concept of free standing refers to the ability to transfer the foil, and the “freestanding” structure may not actually be unsupported at any time. Thus, the term freestanding is given a broad interpretation that includes releasably bound structures with the ability to transfer the layer even though the “freestanding” foil may never actually be separate form a support surface since the continual support of the foil can reduce the incidence of damage.

Generally, the release layer may differ from the layer above and the substrate below with respect to composition and/or properties, such as density, such that it is susceptible to fracture. The porous release layer can comprise essentially unfused submicron particles or a fused porous network of submicron particles deposited on a substrate. Thus, the porous release layer can be a soot or the like from reactive deposition, which may be in the form of a fused particle network, or nano-powder layer of a high melt temperature material, such as silicon oxide, silicon nitride, silicon oxynitride, silicon carbide, silicon carbonitride, combinations thereof and mixtures thereof. Generally, the porous release layer is formed from a ceramic material that does not melt during a reactive deposition process onto the release layer, and in some embodiments, the release layer also can remain substantially intact following processing of the foil, such as a recrystallization process or other high temperature process.

Whether or not the porous layer comprises fused or unfused particles, in some embodiments it is desirable for the release layer to involve submicron particles such that the surface of the porous layer is not undesirably uneven such that the subsequently deposited layer deposits relatively flat. Following a flame treatment of the release layer, the particulate nature along the surface can be lost as a result of fusing and annealing of the structure without the full collapse of the porous nature of the structure. In general, the porous release layer can have any reasonable thickness, although it may be desirable to use a thickness that is not too large so that resources are not wasted. The release layer should comprise a reasonably thickness since the subsequent overcoat layers should not directly interact with the underlying substrate. The formation of porous, particulate release layers is described further in published PCT application WO 2008/156631 to Hieshnair et al., entitled “Reactive Flow Deposition and Synthesis of Inorganic Foils,” and published U.S. patent application 2007/0212510A to Hieslmair et al., entitled “Thin Silicon or Germanium Sheets and Photovoltaics Formed From Thin Sheets,” both of which are incorporated herein by reference.

A foil transfer apparatus generally comprises appropriate supports for the initial substrate attached to the foil, a structure providing a receiving surface and a corresponding transport system that controls the interaction of the receiving surface with the foil. Optionally, the apparatus can comprise a substrate transport system that moves the substrate as a part of the foil transfer process and/or for moving the substrate into or out from the apparatus. The transport system can be designed with appropriate controls to interface the foil with the receiving surface in register, when appropriate, with moderate pressure to adhere the receiving surface with the foil and moderate force to separate the foil from its substrate. The receiving surface can be associated with an intermediate transfer element or with a receiving superstrate, which itself can be temporary or permanent. With respect to a specific layer transfer process, the foil and initial substrate may comprise a foil associated with a porous release layer or a foil releasably bound to a temporary substrate, such as following one or more previous transfers of the foil with a first transfer involving the fracture of a porous release layer.

If the receiving surface is associated with a superstrate that is incorporated in an ultimate product, the receiving surface generally can be flat, although in principle a cylindrical substrate or other curved substrate could be used. With a flat receiving surface, the foil can be transferred to a temporary receiving surface or the structure can be bent at least slightly for the transfer process. If a flat structure is curved a sufficiently small amount, such as with an elastic deformation, the structure returns to its flat configuration when the forces are released. A glass sheet with reasonable properties generally can be bent or curved a small amount temporarily without overstressing the glass.

If the receiving surface is curved to transfer the foil, the structure can be associated with a gently curved mandrel or the structure with the receiving surface can be gently bent dynamically as the foil is transferred. The receiving surface can be rocked, such as with a motion corresponding to a rocking chair rocker, to pull the foil from the substrate with sequential portions of the receiving surface contacting the foil and with the foil being peeled from the substrate along an edge, which propagates along the substrate as the foil separates. While the substrate can be translated during the separation process, the rocking motion can be performed straightforwardly with a fixed substrate. If the receiving surface is bent dynamically, the structure can be brought adjacent the foil surface with the leading edge of the receiving surface bent to contact the foil. As the foil is peeled away form the substrate, the location of the bend can be gradually moved along the receiving surface to match the propagation of the bound edge of the foil to result in gradually peeling the foil off of the substrate surface.

The receiving surface has an appropriate adhering ability such that an appropriate force can be applied to pull the foil away from the substrate, which may involve fracturing a release layer. The fracture of a release layer frees the foil from the substrate along an edge which propagates from a leading edge. As the foil is pulled away from the substrate, some resilience of the foil provides for some flexing as the release layer fractures. If the release layer and foil have been appropriately engineered and the bending is sufficiently mild, the foil can be separated in this way without any substantial damage to the foil.

In one embodiment of interest, a silicon foil with a dielectric top layer can be transferred to a glass sheet, which can comprise window glass or the like, with an adhesive to hold the foil to a surface of the glass sheet. The glass sheet can form the top glass surface of a photovoltaic module. The rear surface of the silicon foil can be processed to provide for collectors for the photocurrent.

With respect to the use of an intermediate transfer element, the foil generally is then transferred to a temporary receiving surface. The temporary receiving surface can be curved to a desired degree, although the amount of curvature should still provide for avoiding damage to the foil. In some embodiments, the temporary receiving surface can be, for example, a gently curved surface shaped like a rocker to gently rock the foil off of the substrate, or the temporary receiving surface can be on a cylinder or the like if the radius of curvature is sufficiently large that the foil is not excessively bent. A cylindrical receiving surface can be successively rotated to interface with progressively shifted portions of the foil along the length of the foil as the transfer element lifts an edge of the foil away from the substrate onto the receiving surface. The amount of bending appropriate for the foil generally depends on the composition of the foil as well as the internal stresses in the foil.

The temporary receiving surface can store the foil for a period of time or can immediately transfer the foil to another receiving surface, which may or may not be a permanent receiving surface. In some embodiments, the temporary receiving surface interfaces with a portion of the foil as it removes the foil from the substrate and it transfers the foil to a further receiving surface in a continuous motion. The intermediate transfer element can have a surface that has static electricity to releasably grip the surface, suction applicators, and/or a tacky surface, for example, with adjustable adhesive strength that varies by temperature or other controllable environmental parameter. A second receiving surface can be used to receive a foil from the intermediate transfer element after at least a portion of the foil is moved away from the initial substrate due to movement of the intermediate transfer element.

As noted above, a particular inorganic foil can undergo one or more layer transfers. If a plurality of transfers is performed, these can be performed sequentially using the same apparatus or using different apparatuses specifically designed to accommodate the structures at different stages of processing. The foils can be subjected to various processing steps and/or cleaning steps, if desired, between layer transfers. The layer transfers can selectively provide different surfaces of the foil to be exposed for further processing.

In order to reduce the use of silicon in solar cells, thin foils with an average thickness from about 5 microns to about 100 microns of polycrystalline silicon can be desirable to achieve a high efficiency with a modest consumption of materials. In some embodiments, the inorganic foils, e.g., silicon sheets, can have a large area as well as being thin. For example, the foils can have a surface area of at least about 900 square centimeters. For silicon foils and perhaps other polycrystalline inorganic materials, the electronic properties can be improved in some embodiments through the recrystallization of the silicon following the initial formation of the thin silicon layer. A zone melt recrystallization process can be applied to improve the electrical properties, such as carrier lifetimes, of the silicon material.

While a primary application of interest is the manufacture of solar cells, other applications include, for example, flat panel displays. Flat panel displays from large area silicon foils are described further in the published patent application US 2007/0212510A referenced above.

Foil Structure and Formation with Scanning Reactive Deposition

The foils of particular interest herein has a sufficient thickness to provide reasonable mechanical integrity while being thin enough such that the amount of material used is modest. At the desired ranges of thicknesses, the foils generally exhibit some flexibility even though the foils are formed from inorganic materials, such as ceramics and/or crystalline materials. While in principal the layer transfer techniques can be applied to inorganic foils formed using any approach, the ability to form thin and uniform inorganic layers using directed flow reactive deposition approaches onto a porous release layer can allow for efficient inorganic foil formation over a range of desirable compositions and with desirable properties. In particular, reactive deposition approaches provide the ability to form high quality coatings with selected compositions that can form the basis for inorganic foil and/or release layer formation. Release layers generally have sufficiently low mechanical cohesion such that the release layers fragment at low enough amounts of mechanical force that the release layer can be fragmented without significantly damaging the inorganic foil.

While the release layer should fracture as a sacrificial layer to provide for layer transfer, the release layer can be sufficiently mechanically stable to provide for some manipulation of the foil in contact with the release layer without premature de-lamination or partial de-lamination of the foil from the substrate. Furthermore, it is desirable for the release layer to have a relatively smooth surface without excessive interpenetration of the foil material into the release layer. While the density of the release layer can be controlled during its formation, desirable adjustment of the release layer properties has been found through the processing of the release layer after its formation. In particular, the release layer can be passed through a combustion flame to partially densify the release layer and to smooth the surface of the release layer. Alternatively or additionally, a small amount of dense inorganic material can be deposited onto and/or into the release layer using chemical vapor deposition with a majority of the stabilizing composition being embedded within the porous particulate material of the release layer. Alternating layers of LRD™ deposition and Scanning CVD deposition can be performed to form a stable but sufficiently fracturable release layer onto which the foil can be deposited. The flame treatment and the deposition of a stabilization or joining composition alone or combined provide a smoother surface for foil deposition as well as a surface that undergoes a reduce amount of interpenetration with the foil composition following its deposition.

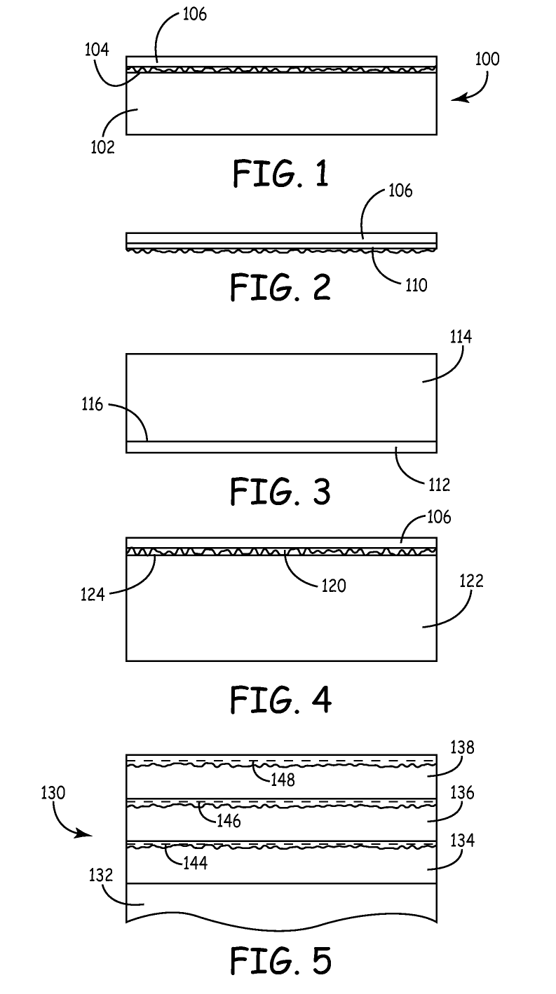

Generally, the foil is formed in a structure comprising a substrate, a release layer on the substrate and the foil on the release layer, and the foil can be subsequently transferred using the approaches described herein. In this initial structure, the foil has the appearances of a film or a coating layer, but the release layer provides for the ability to separate the foil from the substrate. Referring to FIG. 1, initial foil structure 100 comprises substrate 102, release layer 104 and inorganic foil 106. The foil composition, when deposited by reactive deposition, may or may not have need of further processing, such as a heat treatment, to provide sufficient mechanical cohesion to be considered a foil.

A separate foil 106 is shown in FIG. 2. In this embodiment, remnants 110 of release layer 110 are associated with a surface of foil 106. These remnants 110 can be removed through polishing/cleaning/etching, although the polishing/cleaning/etching may remove a minor surface portion of the foil. Referring to FIG. 3, a foil 112 is shown associated with a support substrate 114 along a receiving surface 116. As shown in FIG. 3, any remnants of a release layer have been removed. Referring to FIG. 4, foil 106 is shown with remnants 120 of a release layer in association with a support substrate 122. Remnants 120 are located along a receiving surface 124 of support substrate 122.

In general, substrate 102 can comprise one or more layers. Substrate 102 can be a rigid or flexible material. For example, flexible ceramic sheets are available that can withstand high temperatures. Specifically, Nextel™ woven ceramic fabrics from 3M can be used as substrates. However, rigid substrates can be more convenient for embodiments in which the substrate is reused. The term substrate is used in the broad sense of the material surface contacting the release layer on which the release layer was deposited, whether or not the substrate surface layer was itself deposited as a coating on a further underlying substrate.

In some embodiments, high quality rigid structures can be used as substrates, such as silicon wafers, silicon carbide slabs or the like. The substrate can be a high melting ceramic material, such as silicon carbide, which can be resistant to thermal stresses. Following fracture of the release layer and removal of the foil, the substrates can be reused for subsequent deposition steps, so that a single substrate can be used to form a plurality of foil sheets. The substrate can be cleaned and/or polished following the removal of a foil to remove remnants of the release layer. The cleaned substrate surface can then be ready for the formation of a subsequent release layer and foil sheet. Thus, an expensive substrate can be used for foil formation in a lower cost overall process since the substrate can be reused. The substrate can have a textured or contoured surface for the deposition. A texture or contour on the substrate surface can be transferred at least in part to the foil through the release layer to form a texture on the foil surface.

Release layer 104 provides the ability to perform a deposition of an inorganic layer onto the release layer with the ability to separate the over-layer as an inorganic foil. A release layer has a property and/or composition that distinguish the release layer from adjacent materials, although the release layer can have multiple layers and/or a non-uniform composition or properties across its thickness. In some embodiments, moderate interactions can be applied to the release layer to remove or fracture the release layer to detach the subsequently deposited layers as a substantially intact foil. In some embodiments, the release layer is a porous, particulate layer with fused or unfused particles. A porous, particulate release layer can be formed using a reactive deposition approach, such as light reactive deposition, or through the deposition of a powder coating using a particle dispersion.

Suitable physical properties of a release layer can be, for example, low density, high melting/softening point, low mechanical strength, large coefficient of thermal expansion or combinations thereof. In addition, the material of the release layer generally should be inert with respect to the other materials in the structure at conditions of relevant processing steps, such as at high temperature in some embodiments. The selected properties of the release layer can be exploited to separate an over-layer(s) from the underlying substrate. For the formation of silicon foils on top of the release layer, the release layer can comprise, for example, silicon based ceramic compositions, such as silicon oxide, silicon nitride, silicon oxynitride, silicon carbide, silicon carbonitride or the like.

In general, the release layer can have an appropriate thickness within broad ranges without damaging the function of the layer. Since the release layer may not be used functionally once the overcoat is released, it may be desirable to keep the release layer thin to consume fewer resources. However, if the release layer is too thin, certain properties, such as mechanical strength, isolation of the substrate and ability to separate the over-coat layer from the substrate below the release layer, may be compromised. In some embodiments, the release layer can have a thickness from about 50 nanometers (nm) to about 250 microns, in further embodiments from about 500 nm to about 200 microns and in additional embodiments from about 1.0 microns to about 180 microns. A person of ordinary skill in the art will recognize that additional ranges of release layer thickness within the explicit ranges above are contemplated and are within the present disclosure.

A release layer does not necessarily have the same composition through the layer, and the release layer can have multiple layers, which can have different compositions and/or properties, such as porosity or other morphology, relative to other layers. For example, it can be desirable to deposit a second porous, particulate layer having a smaller average primary particle size so that the layer forms a flatter denser surface for subsequent dense layer deposition. If the first porous, particulate layer has a lower density, it provides more facile fracture to provide the release function while the second layer provides for a gradual transition such that the dense over-layer(s) have more desirable properties and uniformity.

In further embodiments, the release layer can comprise multiple layers with a porous particulate layer and a thin dense CVD layer in which a significant portion of the CVD layer is embedded below the surface of the porous particulate layer. This structure can be repeated to form a multiple layer, release layer. Referring to FIG. 5, an example embodiment of a multiple layer release layer 130 is shown. Release layer 130 is on substrate 132. Release layer 130 comprises porous particulate layers 134, 136, 138 and dense CVD deposited layers 144, 146, 148. CVD layers 144, 146, 148 interpenetrate into respective porous layers 134, 136, 138. In some embodiments, the portion of the CVD layer is embedded in the adjacent porous layer can be at least about 50 weight percent and in further embodiments at least about 60 weight percent. Essentially all of the CVD material can be embedded in the porous layer based on a visual observation of a micrograph, while a visually distinct transition layer can have a higher portion of CVD material. The amount of the embedded material can be evaluated with the estimated amount of deposited material and an observation of a scanning electron micrograph to evaluate the volume of material not embedded within the porous layer, which is subtracted from the total amount of material. The dense CVD layer generally has a quantity of material corresponding to an un-embedded thickness that is from about 5 percent to about 50 percent of the porous layer thickness, in other embodiments from about 7.5 percent to about 35 percent and in further embodiments from about 10 percent to about 30 percent of the porous layer thickness. A person of ordinary skill in the art will recognize that additional ranges of embedded portions and un-embedded CVD layer thicknesses are contemplated and are within the present disclosure. As shown in FIG. 5, there are three repeated sets of porous layers and dense CVD layers, while in other embodiments there can be a single set, two sets, four sets or more than four sets.

Because a porous particulate release layer is mechanically compliant, the release layer can absorb differences of thermal expansion between the substrate and the subsequently deposited over layers to reduce thermal distortion, which can damage the substrate. This advantageous property of the release layer allows a wider variety of substrates and increases the re-use lifetime of the substrates. Also, a porous, particulate layer deposited as the release layer can be selected to be slightly or partially sinterable at high temperatures in order to provide additional mechanical stability while maintaining a high relative mechanical fragility to the release layer. A highly porous yet slightly sintered powder can maintain some rigidity and adhesion at high temperatures while fracturing appropriately. In some embodiments, fracturing can be facilitated during cooling of the resulting structure with the over-layer(s) as influenced by the accompanying thermal expansion mismatch between substrate and deposited over-layers.

The release layer can be further modified through the contact of the release layer with a flame. In addition, the surface of the layer can be modified to be smoother and to decrease the surface porosity as a result of the fusing of the particulates without the full densification of the material. This decrease in surface porosity can be reflected in a reduced interpenetration of a CVD deposited overcoat. Penetration can be reduced to a depth corresponding to the roughness of the material, as little as 100 nm.

In some embodiments, the release layer can exhibit other special, desirable properties, such as texture in its surface and/or a low thermal conductivity value. The texture of the release layer may reflect a texture of the underlying substrate. Furthermore, the texture of the surface of the release layer may be imprinted on subsequently deposited layers. For photovoltaic applications, the texture on the subsequent layers that form the foil can be used in solar cells to scatter light and enhance internal reflectance (i.e. light trapping). With respect to the low thermal conductivity value of the release layer, less thermal energy may be wasted by conduction to the substrate if subsequently deposited layers require heat treatment. A low thermal conductivity may follow from the low density of the release layer as well as the composition.

For the mechanical fracturing of the release layer, while the low mechanical strength of the release layer material can facilitate fracture of the release layer, generally it is desirable for the release layer to have a lower density than the surrounding materials to facilitate its selected fracture. In particular, the release layer can have a porosity of at least about 35 percent, in some embodiments at least about 40 percent and in further embodiments from about 45 to about 95 percent porosity. A person of ordinary skill in the art will recognize that additional ranges of porosity within the explicit ranges above are contemplated and are within the present disclosure. Porosity is evaluated from a scanning electron microscopy (SEM) evaluation of a cross section of the structure in which the area of the pores is divided by the total area.

To provide a desired porosity, the release layer can be deposited with a lower density than surrounding materials. Also, in some embodiments, the lower density of the release layer can be maintained due to reduced or eliminated densification of the release layer in post deposition processing while an over-layer and, optionally, an under-layer are more fully densified, either as deposited or following post deposition processing. This difference in densification can be the result of having a release layer material with a higher flow temperature than surrounding undensified material and/or a larger primary particle size that results in a higher flow temperature. For these embodiments, the densification of the over-layer and, optionally, of an under-layer can result in a release layer with a lower density than the surrounding materials and with a correspondingly low mechanical strength. This lower mechanical strength can be exploited to fracture the release layer without damaging the over-layer.

Referring to FIG. 1, foil 106 is located on release layer 104. Foil 106 can comprise one or a plurality of layers, where layers can be distinguished from each other by composition or property, such as density. In general, foil 106 can comprise any reasonable composition that can be formed as a stable layer on a release layer. The broad range of potential compositions is described further below with respect to the deposition approaches. In general, one or more over-layers can be deposited on a porous release layer. Fracturing or otherwise releasing the over-layers at the release layer can result in the inorganic foil.

Generally, foil 106 can be freestanding. The term freestanding refers herein to the transferability, and the “freestanding” structure may not actually be unsupported at any time. The term freestanding herein is given a broad interpretation that includes, for example, releasably bound structures with the ability to transfer the layer even though the “freestanding” foil may never actually be separate from a support substrate since the continual support of the foil can reduce the incidence of damage. Freestanding does not imply the film can support its own weight.

In some embodiments, foil 106 comprises a semiconductor layer comprising elemental silicon, which can comprise a dopant. In particular, it may be desirable to incorporate one or more dopants into a silicon/germanium-based semiconductor material, for example, to form n-type semiconductors or p-type semiconductors. Suitable dopants to form n-type semiconductors contribute extra electrons, such as phosphorous (P), arsenic (As), antimony (Sb) or mixtures thereof. Similarly, suitable dopants to form p-type semiconductors contribute holes, i.e., electron vacancies, such as boron (B), aluminum (Al), gallium (Ga), indium (In) or combinations thereof.

Dopant concentrations can be selected to yield desired properties. In some embodiments, the average dopant concentrations can be at least about 1×10¹³ atoms per cubic centimeter (cm³), in further embodiments, at least about 1×10¹⁴ atoms/cm³, in other embodiments at least about 1×10¹⁶ atoms/cm³ and in further embodiments 1×10¹⁷ to about 5×10²¹ atoms/cm³. With respect to atomic parts per million (ppma), the dopant can be at least about 0.0001 ppma, in further embodiments at least about 0.01 ppma, in additional embodiments at least about 0.1 ppma and in other embodiments from about 2 ppma to about 1×10⁵ ppma. A person of ordinary skill in the art will recognize that additional ranges of dopant concentrations within the explicit ranges above are contemplated and are within the present disclosure.

One or more layers of the foil can comprise a dielectric material. For example, in the formation of some solar cells, it can be desirable to have a dielectric layer adjacent a surface of a silicon layer. In general, suitable dielectric materials for appropriate applications include, for example, metal/metalloid oxides, metal/metalloid carbides, metal/metalloid nitrides, combinations thereof, or mixtures thereof. If the dielectric is adjacent a semiconductor layer comprising silicon and/or germanium, it can be convenient to use a corresponding silicon/germanium composition for the dielectric. Thus, for a silicon-based photovoltaic, it may be desirable to incorporate a silicon oxide, a silicon nitride, a silicon oxynitride, a silicon carbide, a silicon carbonitride, blends thereof, or combinations thereof, as a dielectric adjacent the silicon-based semiconductor. However, it has been found that a thin layer of aluminum oxide on the front surface of a solar cell can improve cell efficiency. (Presentation by researchers from the Eindhoven University of Technology and Fraunhofer Institute at the 33rd IEEE Photovoltaic Specialists Conference, San Diego, Calif., USA, May 11-16, 2008.) Aluminum oxide layers can be deposited efficiently in a scanning mode using LRD™, scanning sub-atmospheric pressure CVD or atmospheric pressure CVD.

In some embodiments, layers of materials, as described herein, may comprise particular layers that do not have the same planar extent as other layers. For example, some layers may cover the entire substrate surface or a large fraction thereof while other layers cover a smaller fraction of the substrate surface. For example, a layer can comprise a window or other opening that provides access to the underlying material. At any particular point along the planar substrate, a sectional view through the structures may reveal a different number of identifiable layers than at another point along the surface.

With respect to layer properties, thickness is measured perpendicular to a plane corresponding to the top surface that has been smoothed to remove all roughness and texture, which can be a direction perpendicular to a planar surface of an underlying substrate. For some applications, the coatings have a thickness in the range(s) of no more than about 2000 microns, in other embodiments, in the range(s) of no more than about 500 microns, in additional embodiments in the range(s) from about 5 nanometers to about 100 microns and in further embodiments in the range(s) from about 100 nanometers to about 75 microns. A person of ordinary skill in the art will recognize that additional range(s) within these explicit ranges and subranges are contemplated and are encompassed within the present disclosure.

While these thin, large area inorganic foils can be formed with a range of materials that can be produced with directed flow reactive deposition approaches, in some embodiments there is particular interest in thin silicon/germanium-based semiconductor materials with or without dopants. Specifically, in some embodiments of large area, thin silicon-based semiconductor foils, the sheets can have an average thickness of no more than about 100 microns. The large area and small thickness can be exploited in unique ways in the formation of improved devices while saving on material cost and consumption. Furthermore, in some embodiments, the thin silicon semiconductor films can have a thickness of at least about 2 microns, in some embodiments from about 3 microns to about 100 microns, and in other embodiments the silicon films have a thickness from about 5 microns to about 80 microns. A person of ordinary skill in the art will recognize that additional ranges of area and thickness within the explicit ranges above are contemplated and are within the present disclosure.

In some embodiments, the release layer and/or foil can be deposited using reactive deposition. The performance of directed-flow reactive deposition approaches can be used to produce coatings with a selected composition from a broad range of available compositions. Specifically, the compositions generally can comprise one or more metal/metalloid, i.e. metal and/or metalloid, elements forming a crystalline, partially crystalline or amorphous material. In addition, dopant(s) can be used to alter the chemical and/or physical properties of the coating. Incorporation of the dopant(s) into the reactant flow can result in an approximately uniform distribution of the dopant(s) through the coating material. Directed-flow reactive deposition approaches of interest include, for example, LRD™ and scanning sub-atmospheric pressure CVD (SSAP-CVD).

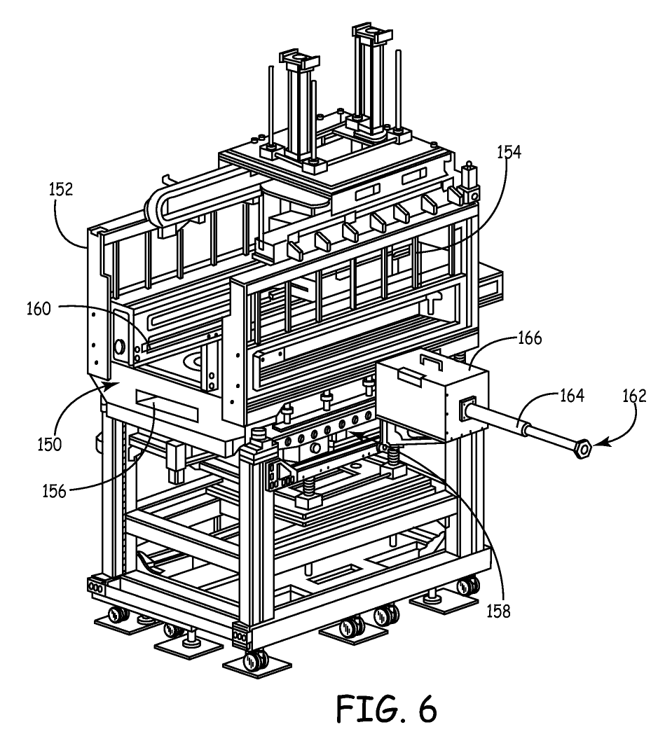

A specific embodiment of a deposition chamber configured for SSAP-CVD and LRD™ deposition is shown in FIG. 6. Deposition chamber 150 comprises chamber 152, a nozzle 154, a substrate slot 156 into chamber 152, a bottom heater 158, a translation module 160 and an optical system 162. Nozzle 154 is operably connected to a reactant delivery system, such as an example system described further below, which can deliver reactants for both the light reactive deposition process and the scanning sub-atmospheric pressure CVD process as well as for the generation of a flame without deposition. Substrate slot 156 is configured to receive a substrate from a substrate handling system and to move the substrate into the deposition chamber. Translation module 160 comprises a stage translated with a worm drive connected to a suitable motor that is configured to transfer rotational motion into translations motion. The stage receives a substrate through slot 156 and subsequently translates the substrate through chamber 152. Optical system 162 comprises a light tube 164 that can form a sealed light beam path from a CO₂ laser, and telescopic optics 166 that can change the beam diameter to a selected size. Apparatuses for the selective reactive deposition using LRD™ or SSAP-CVD is described further in published PCT application WO 2008/156631 to Hieshnair et al., entitled “Reactive Flow Deposition and Synthesis of Inorganic Foils,” incorporated herein by reference.

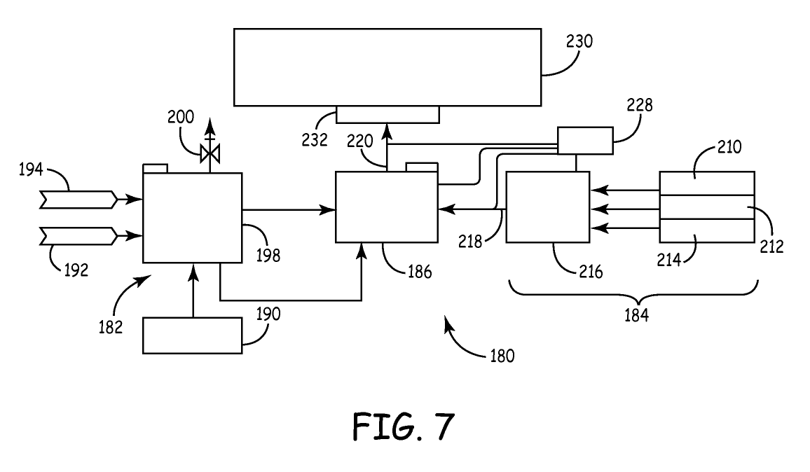

An example embodiment of a reactant delivery system is shown schematically in FIG. 7. As shown in FIG. 7, reactant delivery system 180 comprises a gas delivery subsystem 182 and a vapor delivery subsystem 184 that join a mixing subsystem 186. Gas delivery subsystem 182 can comprise one or more gas sources, such as a gas cylinder or the like for the delivery of gases into the reaction chamber. As shown in FIG. 7, gas delivery subsystem 182 comprises a first gas precursor source 190, a second gas precursor source 192 and an inert gas source 194. The gases combine in a gas manifold 198 where the gases can mix. Gas manifold can have a pressure relief valve 200 for safety.

Vapor delivery subsystem 184 comprises a plurality of flash evaporators 210, 212, 214. Each flash evaporator can be connected to a liquid reservoir to supply liquid precursor in suitable quantities. Suitable flash evaporators are available from, for example, MKS Equipment or can be produced from readily available components. The flash evaporators can be programmed to deliver a selected partial pressure of the particular precursor. The vapors from the flash evaporator are directed to a manifold 216 that directs the vapors to a common feed line 218. The vapor precursors mix within common feed line 218.

The gas components from gas delivery subsystem 182 and vapor components from vapor delivery subsystem 184 are combined within mixing subsystem 186. Mixing subsystem 186 can be a manifold that combines the flow from gas delivery subsystem 182 and vapor delivery subsystem 184. In the mixing subsystem 186, the inputs can be oriented to improve mixing of the combined flows of different vapors and gases at different pressures. A conduit 220 leads from mixing subsystem 186 to reaction chamber 230 through nozzle 232. An inert gas source can also be used to supply shielding gas to a nozzle for appropriate embodiments.

A heat controller 228 can be used to control the heat through conduction heaters or the like throughout the vapor delivery subsystem, mixing system 186 and nozzle 232 to reduce or eliminate any condensation of precursor vapors. A suitable heat controller is model CN132 from Omega Engineering (Stamford, Conn.). Overall precursor flow can be controlled/monitored by a DX5 controller from United Instruments (Westbury, N.Y.). The DX5 instrument can be interfaced with mass flow controllers (Mykrolis Corp., Billerica, Mass.) controlling the flow of one or more vapor/gas precursors. The automation of the system can be integrated with a controller from Brooks-PRI Automation (Chelmsford, Mass.). The reactant delivery system can be used for the delivery of flame reactants, such as ethylene and oxygen, with inorganic precursors turned off for the generation of a flame without any deposition.

In general, coating materials can comprise, for example, elemental metal/metalloid, and metal/metalloid compositions, such as, metal/metalloid oxides, metal/metalloid carbides, metal/metalloid nitrides, metal/metalloid phosphides, metal/metalloid sulfides, metal/metalloid tellurides, metal/metalloid selenides, metal/metalloid arsinides, mixtures thereof, alloys thereof and combinations thereof. Metalloid elements include silicon, boron, arsenic, germanium and tellurium. Reference to elemental metal or elemental metalloid refers to the elemental form of the element, i.e., the unoxidized, M⁰, where M represents the metal/metalloid. Alternatively or additionally, such coating compositions can be characterized as having the following formula:

AₐB_{b}C_{c}D_{d}EₑF_{f}G_{g}H^{h}IᵢJⱼKₖLₗMₘNₙOₒ,

where each A, B, C, D, E, F, G, H, I, J, K, L, M, N, and O is independently present or absent and at least one of A, B, C, D, E, F, G, H, I, J, K, L, M, N, and O is present and is independently selected from the group consisting of elements of the periodic table of elements comprising Group 1A elements, Group 2A elements, Group 3B elements (including the lanthanide family of elements and the actinide family of elements), Group 4B elements, Group 5B elements, Group 6B elements, Group 7B elements, Group 8B elements, Group 1B elements, Group 2B elements, Group 3A elements, Group 4A elements, Group 5A elements, Group 6A elements, and Group 7A elements; and each a, b, c, d, e, f, g, h, i, j, k, l, m, n, and o is independently selected and stoichiometrically feasible from a value in the range(s) from about 1 to about 1,000,000, with numbers of about 1, 10, 100, 1000, 10000, 100000, 1000000, and suitable sums thereof being contemplated. The materials can be crystalline, amorphous or combinations thereof. In other words, the elements can be any element from the periodic table other than the noble gases. As described herein, in suitable contexts all inorganic compositions are contemplated, as well as all subsets of inorganic compounds as distinct inventive groupings, such as all inorganic compounds or combinations thereof except for any particular composition, group of compositions, genus, subgenus, alone or together and the like.

Release layers can be formed using reactive deposition or through the deposition of submicron particles from a dispersion. In particular, a porous, particulate release layer can be formed from a dispersion of submicron particles that are deposited onto a substrate to form the release layer as a particle coating on a substrate surface. The particles can be delivered in a dispersion with or without surface modification, which can be used to stabilize the dispersion. To facilitate the formation of a uniform release layer, the particles can be well dispersed into a liquid for forming the release layer. In some embodiments, the average primary particle size is no more than about a micron, in further embodiments no more than about 100 nm and in additional embodiments form about 2 nm to about 75 nm. A person of ordinary skill in the art will recognize that additional ranges of average primary particle size within the explicit ranges above are contemplated and are within the present disclosure. Laser pyrolysis provides a suitable approach for the synthesis of suitable powders for dispersing into appropriate coating solutions. Laser pyrolysis is suitable for the synthesis of a large range of particle compositions as described further in published U.S. patent application 2006/0147369A to Bi et al., entitled “Nanoparticle Production and Corresponding Structures,” incorporated herein by reference.

If the particles are well dispersed with a suitable secondary particle size, the dispersion can be deposited into a resulting layer having an appropriate packing density, which is generally no more than about 60 percent, and in some embodiments at least about 5 percent of the density of the fully densified material. A person of ordinary skill in the art will recognize that additional ranges of packing density within the explicit ranges above are contemplated and are within the present disclosure. The powder coating can be evaluated for porosity essentially as described above to evaluate the nature of the release layer.

The dispersion generally can be relatively concentrated with a particle concentration of at least about 0.5 weight percent. The well dispersed particles can be deposited onto a substrate using appropriate coating techniques, such as spray coating, dip coating, roller coating, spin coating, printing and the like. The dispersing liquid can be removed by evaporation following the deposition process. The deposited particle coating can be dried and, optionally pressed to form the release layer. The formation of good dispersion of submicron inorganic particles is described further in copending U.S. patent application Ser. No. 11/645,084 to Chiruvolu et al., entitled “Composites of Polymers and Metal/Metalloid Oxide Nanoparticles and Methods for Forming These Composites,” incorporated herein by reference.

In some embodiments, release layers can be formed using reactive deposition. In particular, LRD™ can deposit powder coatings with an appropriate porosity for the use of the coating as a release layer. Furthermore, LRD™ has been used for the deposition of a wide range of compositions, such that an appropriate composition can be selected for the appropriate use as a release layer. Reactant precursors can be delivered for LRD™ as gas, vapor and/or aerosol forms. The use of LRD™ for the formation of a porous, particulate release layer is described further in U.S. Pat. No. 6,788,866 to Bryan, entitled “Layer Materials and Planar Optical Devices,” published U.S. patent application 2007/0212510A to Hieslmair et al., entitled “Thin Silicon or Germanium Sheets and Photovoltaics Formed From Thin Sheets,” and published PCT application WO 2008/156631 to Hieslmair et al., entitled “Reactive Flow Deposition and Synthesis of Inorganic Foils,” each of which is incorporated herein by reference.

A porous, particulate layer formed with LRD™ or from a particle dispersion can be modified following deposition to modify the properties of the as deposited coating. For example, the nozzle of an LRD™ apparatus can be used to form a flame based on the combustion of flammable agents, such as ethylene and O₂, in which ethylene absorbs infrared light so that a CO₂ laser or the like in an LRD™ apparatus can ignite the reactants to form the flame. Since there are no inorganic precursors delivered for this step, the flame does not deposit any coating compositions so that the flame simply modifies the coating. The flame can be scanned across the release layer in the same way that the coating deposition is scanned across the substrate. Alternatively or additionally, a flame treatment can be performed on a porous particulate release layer in a separately designed apparatus. Alternative fuels, such as acetylene, can be used to fuel the flame, and the conditions in the flame can be adjusted to achieve the desired temperatures.

The flame can densify the initially deposited porous coating. While the density of the coating deposited using LRD™ can be adjusted through selection of coating conditions, the use of a flame to densify the porous coating provides additional versatility and provides desirable modification of the coating surface. In some embodiments, the flame treatment can reduce the thickness at least about 35% relative to the initial thickness, in additional embodiments at least about 45%, and in other embodiments from about 50% to about 90%. In other words, as a specific example, an initially porous layer with a thickness of 100 microns can be reduced with a flame treatment for a thickness of 40 microns for a reduction in thickness of 60%. A person or ordinary skill in the art will recognize that additional ranges of thickness reduction within the explicit ranges above are contemplated and are within the present disclosure. Of course, large thickness reductions imply that the initially deposited coating has a low density relative to the fully densified material, and it can be desirable to have an initially low dense porous layer so that the flame processing provides selectability with respect to the modification of the release layer to yield desired properties. To provide desired modification of the porous coating properties, the flame temperature can be adjusted through a control of the flow of flammable compositions into the flame, and the flame can be scanned over the coating one time, two times, three times, four times, five times or more than five times. Generally, each scan covers the entire surface, and the scanning rate can be selected to achieve the desired flame modification of the porous layer.

In addition to the densification of the porous layer when it is passed through the flame, the flame treatment can also modify the surface morphology. In particular, the fusing of the particles along the surface in the heat of the flame results in a smoother surface and a surface that is less susceptible to surface penetration during subsequent CVD coating steps.

Alternatively or additionally, an as deposited porous, particulate layer can be coated with a composition using a dense deposition to reinforce the top surface of the porous layer. In general, the dense deposition process can be performed using LRD™ configured for dense deposition or a selected version of CVD. However, it can be convenient to deposit this stabilizing material using scanning CVD, which can SSAP-CVD or AP-CVD. Specifically, SSAP-CVD deposition can generally be performed with the same reaction chamber and nozzle that is used to perform an LRD™ deposition of a porous layer if the laser is turned off and the reactants are appropriately selected for the SSAP-CVD deposition. Examples are given below involving the sequential depositions of a porous particulate layers and SSAP-CVD layers.

In some embodiments, the amount of material deposited using the dense deposition onto the porous layer can be selected such that a significant fraction of the dense composition is incorporated into the porous structure. The quantity of dense stabilizing composition can be described in terms of the average thickness of a layer if the composition were deposited onto a flat, non-porous substrate. In some embodiments, this average thickness can be from about 0.25 microns to about 10 microns, in further embodiments from about 0.5 microns to about 7.5 microns and in other embodiments from about 1 micron to about 5 microns. In general, the stabilizing composition can be selected such that a significant fraction of the stabilizing composition is embedded within the porous structure when deposited by the dense deposition approach. In particular, a majority of the stabilizing composition can be embedded within the porous structure and in further embodiments at least about 75 percent of the material is within the pores. The amount of material within the pores can be evaluated through visual observation of a cross section with SEM in which any material extending beyond the porous structure can be identified as a visual dense layer on the porous structure. In some embodiments, essentially all of the stabilizing or joining material is within the pores as determined by the lack of a clearly distinguishable dense layer over the porous layer. However, the penetration of the dense material within the porous structure forms a visible interfacial layer in which the densely deposited reaction products are prominent, although the dense composition can percolate through the entire porous structure. The stabilization material can comprise the same chemical composition as the porous composition or a different chemical composition, although it can be convenient to use the same chemical composition so that the material exhibits the similar thermal expansion properties in subsequent processing.

The overcoat structure for the foil can be formed with one or more additional deposition steps and optionally with further processing while the structure is associated with the release layer. LRD™ as well as SSAP-CVD can be used to deposit an over-layer onto a porous, particulate release layer while maintaining the ability of the release layer to fracture to release the over-layer as an inorganic foil.

To form silicon-based materials using LRD™, gaseous silanes can be conveniently supplied in the reactant flow, and the reactant flow can comprise secondary reactants such as molecular oxygen (O₂), ammonia (NH₃), or hydrocarbons, such as ethylene (C₂H₄) to supply the non-silicon atoms for dielectric or other material formation. The reactant flow can also include inert diluent gases to moderate the reaction. LRD™ is described further in published U.S. patent application 2003/0228415A, to Bi et al., entitled “Coating Formation by Reactive Deposition,” incorporated herein by reference.

For material synthesis in a reactive flow by LRD™, suitable oxygen sources include, for example, O₂, N₂O or combinations thereof, and suitable nitrogen sources include, for example, ammonia (NH₃), N₂ and combinations thereof. The range of compositions available with light reactive deposition is described further in copending U.S. patent application Ser. No. 11/017,214 to Chiruvolu et al., entitled “Dense Coating Formation by Reactive Deposition,” incorporated herein by reference.

For CVD deposition, suitable precursors for Si include, for example, silane (SiH₄) and disilane (Si₂H₆). Suitable Ge precursors include, for example, germane (GeH₄). Suitable boron precursors include, for example, BH₃ and B₂H₆. Suitable P precursors include, for example, phosphine (PH₃). Suitable Al precursors include, for example, AlH₃ and Al₂H₆. Suitable Sb precursors include, for example, SbH₃. Suitable precursors for vapor delivery of gallium include, for example, GaH₃. Arsenic precursors include, for example, AsH₃.

In addition, multiple layers of coating material can be deposited in a controlled fashion to form foil layers with different compositions. Similarly, the coating can be made a uniform thickness, or different portions of the substrate can be coated with different thicknesses of coating material. Different coating thicknesses can be applied such as by varying the sweep speed of the substrate relative to the particle nozzle, by making multiple sweeps of portions of the substrate that receive a thicker coating or by patterning the layer, for example, with a mask. Alternatively or additionally, a layer can be contoured by etching or the like following deposition. The directed flow reactive deposition approaches described herein can be effective for forming high quality coatings for applications in which an appropriate coating thickness is generally moderate or small, and very thin coatings can be formed as appropriate.

Due to the relatively high deposition rate combined with the high coating uniformity with deposition approaches herein, large substrates can be effectively coated. With larger widths of the substrate, the substrate can be coated with one or multiple passes of the substrate through the product stream. Specifically, a single pass can be used if the substrate is roughly no wider than the inlet nozzle of the reactor such that the product stream is approximately as wide as or somewhat wider than the substrate. With multiple passes, the substrate is moved relative to the nozzle with the length of an elongated opening from the nozzle in a direction oriented along the width of the substrate. Thus, it is straightforward to coat substrates in some embodiments with a width of at least about 20 centimeters, in other embodiments at least about 25 cm, in additional embodiments from about 30 cm to about 2 meters, in further embodiments no more than about 1.5 meters and in some embodiments no more than 1 meters. A person of ordinary skill in the art will recognize that additional ranges of widths within these explicit ranges are contemplated and are within the present disclosure.

In general, for convenience, the length is distinguished from the width of a substrate in that during the coating process, the substrate is generally moved relative to its length and not relative to its width. With this general principle in mind, the distinction may or may not be particularly relevant for a particular substrate. The length is generally only limited by the ability to support the substrate for coating. Thus, lengths can be at least as large as about 10 meters, in some embodiments from about 10 cm to about 5 meters, in further embodiments from about 30 cm to about 4 meters and in additional embodiments from about 40 nm to about 2 meters. A person of ordinary skill in the art will recognize that additional ranges of substrate lengths within these explicit ranges are contemplated and are within the present disclosure.

As a result of being able to coat substrates with large widths and lengths, the coated substrates can have very large surface areas. In particular, substrates sheets can have surface areas of at least about 900 square centimeters (cm²), in further embodiments, at least about 1000 cm², in additional embodiments from about 1000 cm² to about 10 square meters (m²) and in other embodiments from about 2500 cm² to about 5 m². With the ability to form thin structures through the use of a release layer, the large surface areas can be combined with particularly thin structures. In some embodiments, the large surface area inorganic foils can have a thickness of no more than about a millimeter, in other embodiments no more than about 250 microns, in additional embodiments no more than about 100 microns and in further embodiments from about 5 microns to about 50 microns. A person of ordinary skill in the art will recognize that additional ranges of surface area and thickness within the explicit ranges above are contemplated and are within the present disclosure.

For appropriate directed-flow embodiments at sub-atmospheric pressures, a CVD deposition process can be termed scanning sub-atmospheric pressure chemical vapor deposition (SSAP-CVD). In some embodiments, the porous release layer can be deposited with LRD™ followed by the deposition of a silicon layer and optionally additional layers using SSAP-CVD within the same reactor, in which the laser is turned off prior to performing the SSAP-CVD deposition step. Atmospheric pressure CVD can also be performed. In some embodiments, the SSAP-CVD process can have greater control over the thermal processes of the deposition so that in principle a more uniform layer can be formed relative to atmospheric pressure CVD. However, other forms of CVD generally can also take advantage of deposition on a porous layer to facilitate separation of the resulting layer as well as reducing strain. Although SSAP-CVD offers certain advantages, CVD can be performed in an LRD™ chamber at other pressures, such as at atmospheric pressure or higher than atmospheric pressure. Thus, for certain applications the SSAP-CVD process can offer certain advantages over other CVD processes with respect to the maintenance of a high deposition rate while within an LRD™ chamber, and in some embodiments prior and/or subsequent layers can be deposited with the versatile composition range available through either LRD™ process or the SSAP-CVD process.

The over-layers can be subjected to further processing following deposition prior to separation of the inorganic foil or prior to further device formation. For example, heat treatment can be used to densify and/or anneal coatings. To densify the coating materials, the materials can be heated to a temperature above the melting point for crystalline materials or the flow temperature for amorphous materials, e.g., above the glass transition temperature and possibly above the softening point below which a glass is self-supporting, to consolidate the coating into a densified material by forming a viscous liquid. Sintering of particles can be used to form amorphous, crystalline or polycrystalline phases in layers. The sintering of crystalline particles can involve, for example, one or more known sintering mechanisms, such as surface diffusion, lattice diffusion, vapor transportation, grain boundary diffusion, and/or liquid phase diffusion. The sintering of amorphous particles generally can lead to the formation of an amorphous film. With respect to release layers, a partially densified material can be a material in which a pore network remains but the pore size has been reduced and the solid matrix strengthened through the fusing of particles.

Heat treatments for coated substrates can be performed in a suitable oven. It may be desirable to control the atmosphere in the oven with respect to pressure and/or the composition of the surrounding gases. Suitable ovens can comprise, for example, an induction furnace, a box furnace or a tube furnace with gas(es) flowing through the space containing the coated substrate. The heat treatment can be performed following removal of the coated substrates from the coating reactor. In alternative embodiments, the heat treatment is integrated into the coating process such that the processing steps can be performed sequentially in the apparatus in an automated fashion. Suitable processing temperatures and times generally depend on the composition and microstructure of the coatings.

In some embodiments, it is desirable to perform zone melt recrystallization of a silicon layer to increase the crystal size relative to the initial polycrystalline or amorphous silicon and to improve correspondingly the electrical properties of the semiconductor. In zone melt recrystallization, generally the coated substrate is translated past a strip heater that melts the silicon along a stripe. For example, a focused halogen lamp can be used as the linear heat source. A heater can be placed below the structure to control the base temperature of the structure. The melted material crystallizes as it cools after translating away form the heating zone. The crystals grow along a crystallization front. The speed of movement of the heater is controlled to adjust the distance between the melting front and the solidification front. There is a balance between a faster sweep speed that reduced processing costs with a slower sweep speed to get larger crystal grains and fewer crystal defects.

The objective of zone melt recrystallization is to increase the crystal size of the polycrystalline silicon upon completion of the recrystallization. When the silicon is melted, the surface of the material may not remain flat. Therefore, it can be desirable to have a capping layer of a high melting ceramic over the silicon layer that constrains the liquid silicon after it is melted. The zone melt recrystallization process can be advantageously adapted for embodiments which account for the thermal insulation of the release layer. The performance of zone melt recrystallization of a silicon film on a release layer is described further in copending U.S. patent application Ser. No. 12/152,907 filed on May 16, 2008 to Hieslmair et al, entitled “Zone Melt Recrystallization for Inorganic Films,” incorporated herein by reference. Specifically, in the case of a high temperature recrystallization step of a subsequently deposited silicon layer, the insulating release layer blocks thermal conduction from the silicon layer into the substrate, thus reducing wasted energy. The recrystallization process can be performed in an insulated chamber such that a base temperature can be maintained without the expenditure of a large amount of energy.

### Foil Transfer Apparatus

A foil transfer apparatus provides for the transfer of an inorganic foil from an initial substrate to a receiving surface, which may involve the fracture of a release layer and/or the release from another adhering force. In general, a foil transfer apparatus can comprise an enclosure, a substrate support, a receiving surface associated with a transfer element, and a transport system. The receiving surface can involve a permanent attachment to the foil such that the transfer element can be a permanent element of an ultimate product, or the receiving surface can be a temporary resting surface such that the transfer element is temporary. The transport system provides for the relative movement of the substrate support and the transfer element to effectuate the foil transfer. Also, the transfer element can comprise a support for holding the transfer element if the transfer element is not a component of the transport system, such as when the transfer element involves a permanent receiving surface that is removed from the apparatus for use of the foil. The receiving surface generally can be a curved surface to provide for a peeling motion for the transfer of the foil.

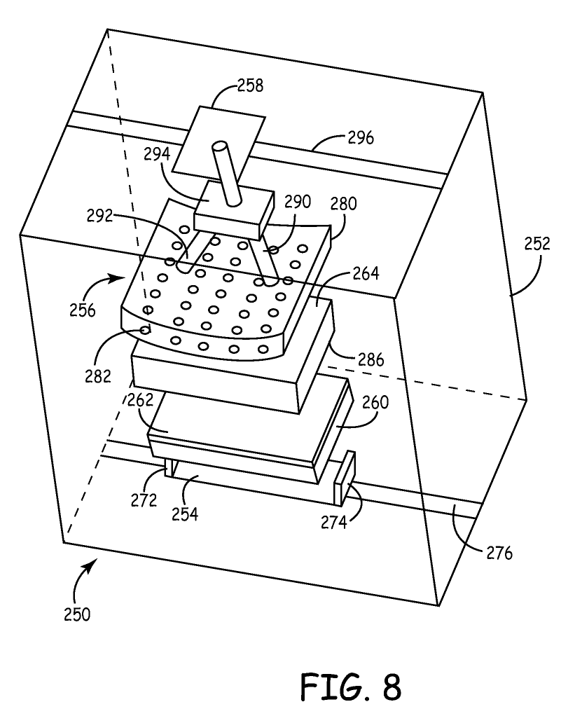

Referring to FIG. 8, an embodiment of a foil transfer apparatus is shown schematically. Apparatus 250 comprises an enclosure 252, substrate support 254, transfer element support 256 and a conveyor system 258. For convenience, enclosure 252 is shown as transparent such that structure within the enclosure can be seen. A substrate 260 with a foil 262 is shown slightly displaced from its position associated with substrate support 254, and an optional receiving body 264 is shown displaced slightly from a position associated with transfer element support 256.

Enclosure 252 can be formed from any reasonable material, such as stainless steel or the like, which is durable. Enclosure 252 generally keeps out contaminants. During use, enclosure 252 may or may not be at atmospheric pressure. In some embodiments, enclosure may be at a sub-atmospheric pressure. Enclosure 252 can be operable connected through appropriate transport system with other processing chambers, such as deposition chambers, recrystallization chambers or the like. Apparatus 250 is shown with an optional substrate conveyor system 270, which can be used to move the substrate during the transfer process if appropriate and/or to generally move the substrate into position for the transfer, with the further option of conveying the substrate to adjacent process chambers. As shown in FIG. 8, substrate support 254 comprises substrate grippers 272, 274 and a substrate conveyor 276. Any reasonable designs, such as those known in the art, can be used for these components. While the apparatus in FIG. 8 is shown with the foil pointing upward from the transport process, the substrate can have different orientations for the transfer, such as with the foil pointing downward.

Transfer element support 256 comprises a support element 280 with a curved shape. In general, the exact shape of the curve may not be particularly significant, although a shape corresponding to a fragment of a cylindrical surface can be used with a large radius of curvature. The amount of curvature can be very modest while having sufficient shape to provide for the pulling of an edge of the foil. As shown in FIG. 8, the lower surface of support element 280 has suction ports 282 for gripping a structure with a receiving surface using suction, although other mechanisms, such as electrostatic or adhesive bonds, can be used if appropriate. Receiving body 264 has a receiving surface 286, which can be a permanent receiving surface for the foil. Receiving body 264 can have a naturally planar shape, such that adherence onto support element 280 results in curvature of receiving body 264 with resulting strain in the structure. The amount of curvature should be selected such that receiving body 264 is not damaged through the mounting onto support element 280. If the strain is appropriate, receiving body 264 can resume a planar shape after release from support element 280.

In this embodiment, transfer element support 256 further comprises legs 290, 292 and actuator 294. Legs 290, 292 connect support element 280 with actuator 294. Actuator 294 moves legs 290, 292 and support element 280 in a rocking type motion to effectuate the transfer of the foil. In particular, a segment of support element 280 contacts the foil, and the rocking motion can take place over a fixed substrate. Conveyor system 258 can lower transfer element support 256 down toward the substrate such that receiving surface 286 can contact the foil. Actuator 294 generally positions an edge of receiving surface 286 to contact the foil as the transfer support element is lowered. After an edge of the receiving surface is adhered to the foil, actuator 294 performs a rocking motion at a selected rate to peel foil 262 from substrate 260. Following completion of the placement of the foil on receiving surface 286, conveyor system 258 can lift support element 280 away from substrate 260. Conveyor system 258 can comprise translator 296 to provide for movement of transfer support element 256. Transfer support element 256 can be moved to deliver foil on receiving surface 286 to a desired location, and/or to translate transfer element support 256 during the foil transfer process, although if a rocking motion is used for the transfer, actuator 294 is not necessarily translated to provide for the transfer. If no receiving body 264 is used, the receiving surface, generally a temporary receiving surface is located along the bottom surface of support element 280.

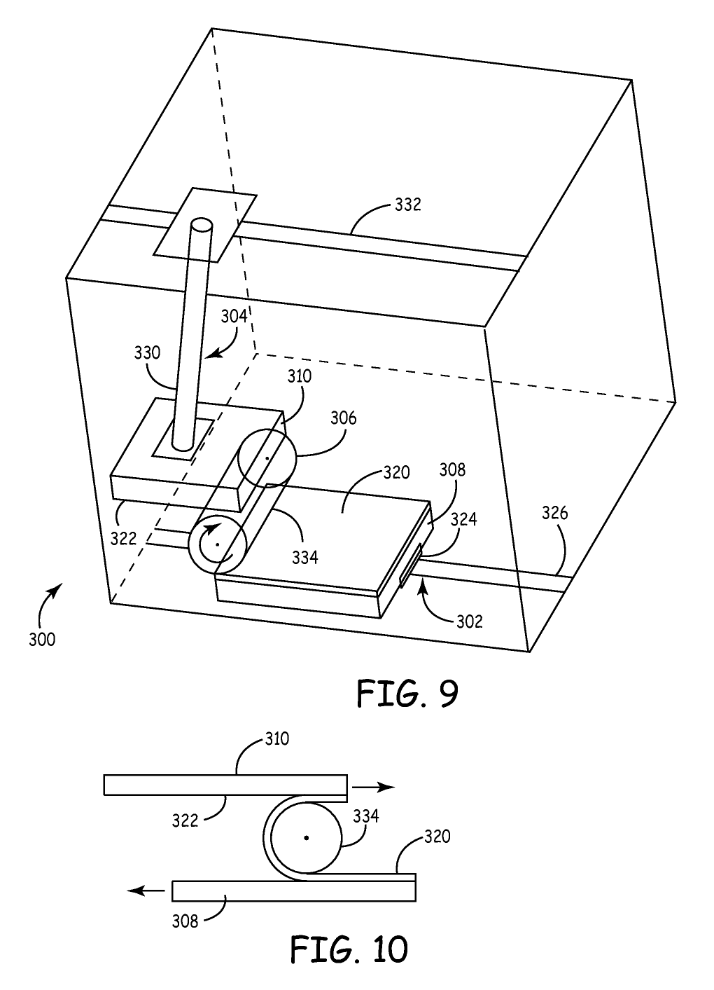

An alternative embodiment of a transport apparatus is shown in FIG. 9. In this embodiment, transfer apparatus 300 comprises a substrate transport 302, a receiving element transport 304, and a transfer roller 306, which interact with substrate 308 and receiving element 310. Foil 320 is initially on substrate 308, and foil 320 is transferred to a planar receiving surface 322 along the bottom of receiving element 310. Substrate transport 302 comprises a substrate support 324, which holds substrate 308, and a substrate conveyor 326, which can translate substrate 308. Receiving element transport 304 comprises a receiving element support 330 and receiving element conveyor 332. Receiving element support 330 generally can raise/lower receiving element 310 as well as supporting receiving element 310. Receiving element conveyor 332 may be able to translate receiving element 310 for effectuating layer transfer as well as for transporting the receiving element 310 to a desired location. The radius of transfer roller 306 can be selected appropriately based on suitable bending of the foil without damaging the foil. This embodiment may not be reasonable for foils that are too limited with respect to bending since the radius of the roller may then be impractically large. Transfer roller 306 has a temporary receiving surface 334, which can hold the foil with suction, electrostatic forces, temporary adhesives or the like.

With respect to temporary adhesives, the use of a thermal sensitive releasable adhesive is described in published U.S. patent application 2006/0124241 to Doi et al., entitled “Method of Thermal Adherend Release and Apparatus for Thermal Adherend Release,” incorporated herein by reference. An adhesive that loses adherence upon stretching parallel to the surface of the adhered layer can be adapted for release and such adhesives are described further in U.S. Pat. No. 5,672,402 to Kreckel et al., entitled “Removable Adhesive Tape,” incorporated herein by reference. Similarly, a vapor or liquid chemical can be used to dissolve or otherwise denature an adhesive to release the adhesive bond. Other adhesives can respond to electric fields. Furthermore, static electricity can be controlled for holding and releasing a layer using alternatively electrical grounding and electrical isolation. These releasable adherence approaches can generally be used with any temporary receiving surface.

In operation, roller 306 generally is rotated roughly half of a revolution prior to initiating transfer of foil 320 to receiving surface 322. Thus, substrate 308 is generally translated prior to translating receiving element 310 to receive foil 320. The partially completed transfer process is shown in FIG. 10. As shown in FIG. 10, foil 320 is partially peeled away from substrate 308 with foil wrapped roughly half way around roller 334. The foil is pulled away form substrate 308 along an edge 340, which can involve the fracture of a release layer at this edge. A portion of foil 320 is adhered to receiving surface 322, which can have an adhesive or other means for gripping foil 320. After placement of the foil onto a permanent receiving surface, an adhesive can be cured if desired.

Various related embodiments of foil transfer apparatuses can be practiced by a person of ordinary skill in the art based on the teachings herein. In some embodiments, the receiving surface can be associated with a flexible sheet or the like or a rigid sheet or other structure. Suitable flexible sheets can be formed, for example, from polymers, metal foils, woven ceramics and combinations thereof. Suitable rigid sheets can comprise, for example, ceramics, such as silica glass, rigid polymer sheets, rigid metal sheets or combinations thereof. For transfer to a fully rigid structure, an embodiment similar to the embodiment of FIG. 9 can be used. If the receiving surface is associated with a structure that can accept a minor amount of flexing, then the embodiment of FIG. 8 can be used. If the receiving surface is used to directly receive the foil from the initial substrate, it can be particularly desirable to use a receiving surface associated with a flexible substrate, especially for embodiments in which the initial substrate is rigid. If the initial substrate is flexible, the initial substrate can be bent gently to facilitate transfer to a receiving surface that is associated with a flexible or rigid sheet.

If the foil is initially transferred from a release layer to a temporary receiving surface, the foil can be subjected to additional layer transfers. These additional layer transfers can be performed with the apparatuses described above. Generally, the foil is ultimately placed in association with a permanent receiving surface. If the foil is held on the permanent receiving surface with an adhesive, the adhesive can be cured, for example, with UV light, if the adhesive is crosslinkable.

After the initial removal from a release layer, the resulting inorganic foil may have a portion of the fractured release layer attached. If desired, remnants of the release layer associated with the inorganic foil can be removed from the release thin structure using appropriate methods, such as etching, cleaning or polishing. Depending on the nature of the release layer material, residual release layer material can be removed with mechanical polishing and/or chemical-mechanical polishing. Mechanical polishing can be performed with motorized polishing equipment, such as equipment known in the semiconductor art. Similarly, any suitable etching approach, such as chemical etching and/or radiation etching, can be used to remove the residual release layer material. Also, substrates can be similarly cleaned to remove residual release layer material using chemical cleaning and/or mechanical polishing. Thus, a high quality substrate structure can be reused multiple times while taking advantage of the high quality of the substrate.

### Applications

In general, inorganic foils can be applicable for a wide range of uses. As noted above, semiconductor foils are of particular interest for applications where the reduce consumption of silicon can be desirable. For example, the silicon foils can be used for the formation of display circuits or for solar cell applications. Due to a predicted growth of the solar cell industry, there is an interest in economic solar cell formation that consumes fewer natural resources and reduce cost, while maintaining or improving performance.

The processing of silicon foils into rear contact solar cells has been described in published U.S. patent application 2008/0202576A to Hieslmair, entitled “Solar Cell Structures, Photovoltaic Panels and Corresponding Processes,” incorporated herein by reference. The layer transfer processes described herein can be used to facilitate the processing of the foil into the solar cell structures. In some embodiments, a zone melt recrystallization step can be performed with the silicon foil attached to a release layer onto which the foil was deposited. The top surface can then be prepared for attachment to a glass substrate with any texturing and/or the formation of a dielectric layer performed with the foil on its original substrate. The foil can then be transferred directly or indirectly to a glass structure that forms the light receiving surface of the solar cell. The remaining processing of the solar cell can then be performed along the rear surface that is exposed after the fracture of the release layer and the transfer of the foil. An entire module or a fraction thereof can be formed from a single sheet of foil as described further in published U.S. patent application 2008/0202577A to Hieslmair, entitled “Dynamic Design of Solar Cell Structures, Photovoltaic Modules and Corresponding Processes,” incorporated herein by reference.

Using the foil transfer approaches described herein, an inorganic foil can be transferred to expose a desired surface for processing, and the inorganic foil can be carefully positioned onto an ultimate receiving surface for incorporation into a product once the adhered surface is processed as desired. These processes are suitable for the handling of very large area foils in a commercial setting.

### EXAMPLES

The depositions for these examples was performed in a light reactive deposition chamber similar to the embodiment shown in FIGS. 8-10 of Published U.S. patent application 2007/0212510A to Hieslmair et al., entitled “Thin Silicon or Germanium Sheets and Photovoltaics Formed From Thin Sheets,” incorporated herein by reference. A reactant delivery system was used that is similar to the apparatus in FIG. 7. The silicon precursor was silane, SiH₄. O₂ was delivered for the formation of the oxide, and inert diluent gas was used as desired to moderate the reactions while maintaining desired flow. The laser was turned off during the scanning sub-atmospheric pressure CVD (SSAP-CVD) deposition steps.

### Example 1

### LRD™ Soot Deposition with CVD Stabilizing Material

This example shows the results of alternating LRD™ porous deposition with CVD dense deposition. In data not shown, 150 micron porous particulate release layer of SiO₂ deposited onto a silicon carbide substrate have been observed to delaminate partially upon the processing of a silicon foil deposited on top of the release layer. This uncontrolled delamination and fracturing of the foil is solved through the additional release layer manipulation described in this example and the following examples.

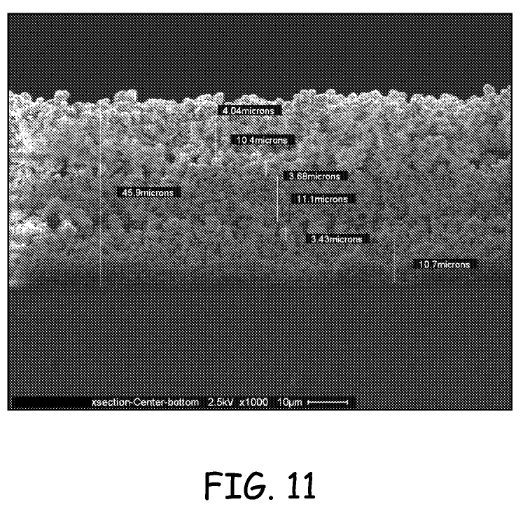

Referring to FIG. 11, a scanning electron micrograph is shown of a cross section of a multiple layered release layer formed on a silicon carbide substrate. This structure was formed from the alternating deposition of a porous, particulate SiO₂ layer using LRD™ deposition followed by a SSAP-CVD deposition of a dense SiO₂ material. The amount of material deposited by SSAP-CVD was approximately corresponding to a 2 micron thick dense layer of SiO₂. CVD product compositions were observed throughout the entire thickness of the structure. However, an interfacial section is observable along the surfaces when CVD deposition was performed, in which the interfacial region has a visibly larger fraction of dense composition within the porous structure. The total average thickness of the final structure is 45.9 microns. The approximate average thicknesses of the three interfacial layers starting from the top are 4.0 microns, 3.7 microns and 3.4 microns. The average thickness of the respective full three layers including the transition layer formed by sequential LRD™-CVD layer depositions are from the top, 14.4 microns, 14.8 microns, and 14.1 microns.

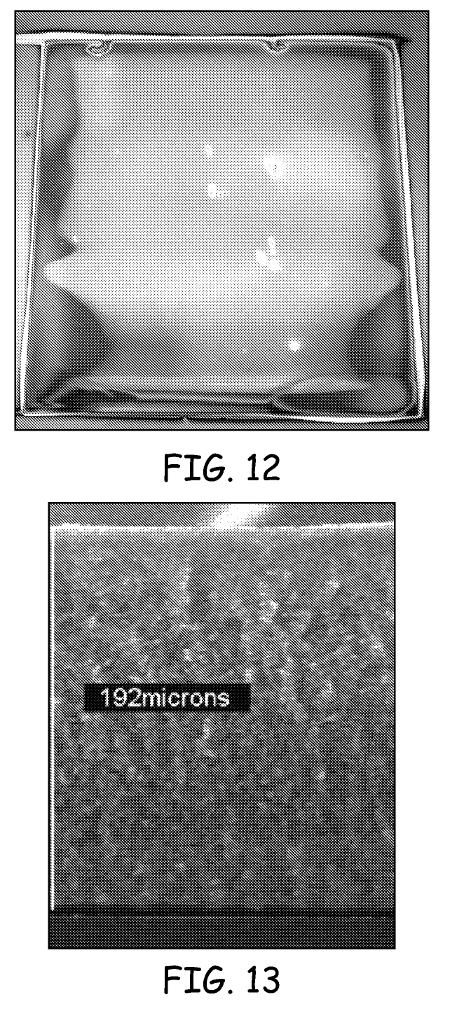

A silicon foil was deposited on top of the layered release layer. The silicon foil was deposited using SSAP-CVD. The silicon foil was subsequently subjected to zone melt recrystallization to improve the crystallinity of the as deposited foil. A top view of the resulting recrystallized foil on a 200 mm×200 mm square substrate is shown in FIG. 12. No uncontrolled de-lamination was observed following the processing of the silicon foil.

### Example 2

### Flame Densification of SiO₂ Soot

This example demonstrates the stabilization of an LRD™ deposited soot through the use of an oxygen-acetylene flame.

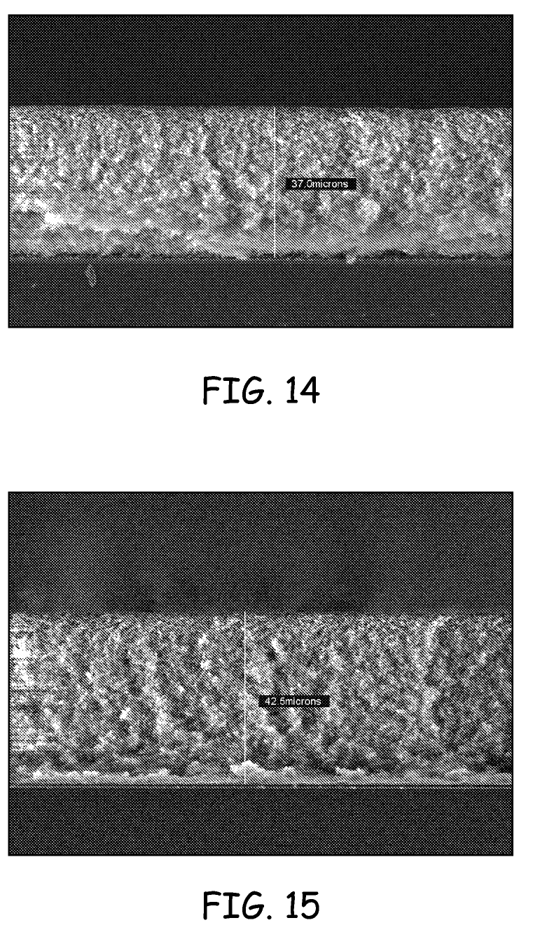

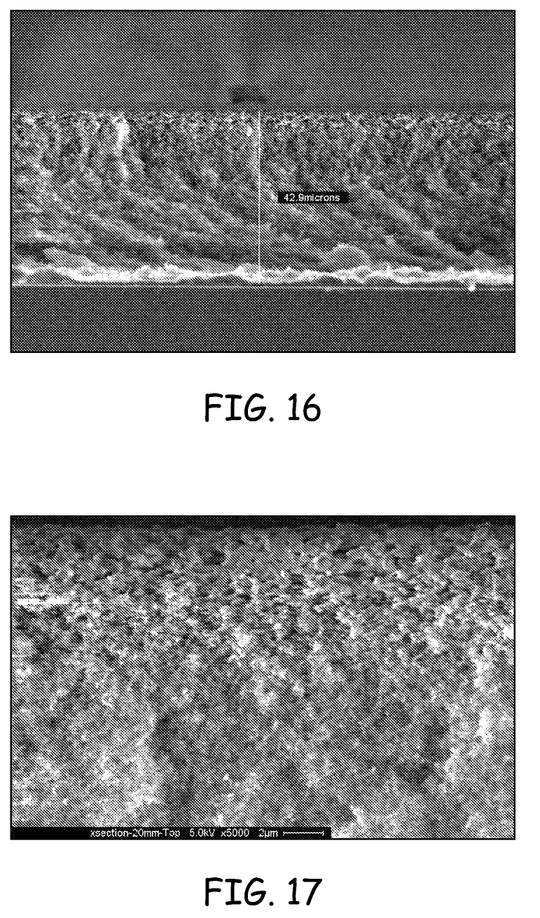

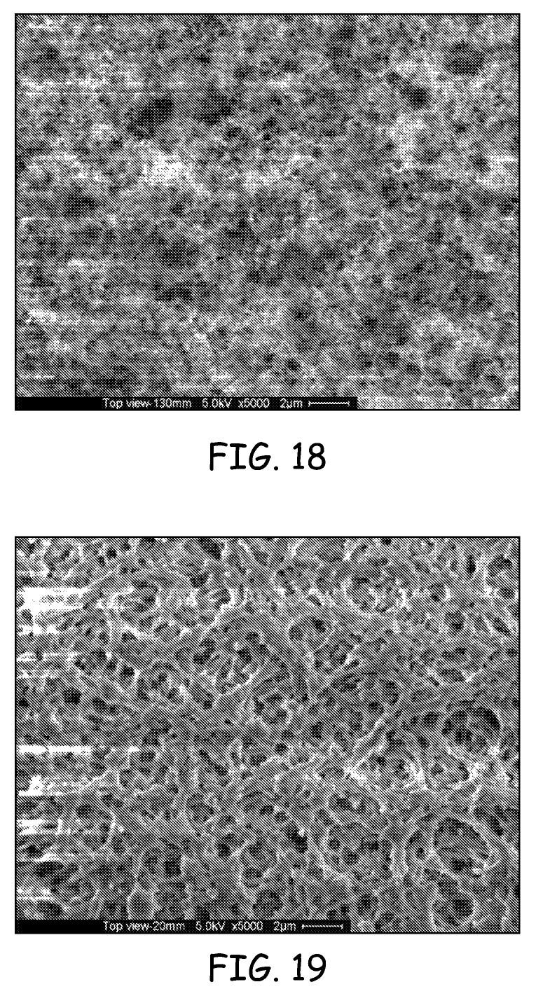

The flame was generated with an oxyacetylene hand torch. The flame was scanned by hand across a 200 mm×200 mm square tile. The flame was passed over the tile in 1, 2, 3 or 4 passes to evaluate the effects of the flame. The initial soot as deposited was about 190 microns thick. Following the passage of the flame over the soot, the layer had thicknesses ranging from about 35 microns to about 43 microns. Within the variation in the thicknesses due to experimental variation, the porous layer thickness was approximately the same after one pass of the flame or with multiple passes of the flame. SEM micrographs of the cross section of porous layers without flame treatment is shown in FIG. 13, and cross sectional views of the soot after the flame treatment SEM are shown in FIGS. 14-16 based on 1, 2, or 3 passes of the flame, respectively. A higher magnification of the porous layer after four passes of the flame is shown in FIG. 17. The top surface of the soot without flame treatment is shown in FIG. 18, and the top surface after 4 passes of the flame is shown in FIG. 19. After flame treatment, the top view of the porous material substantially loses its particulate appearance.

### Example 3

### Silicon Foil Deposition onto a Flame Densified Release Layer

This example shows the properties of a silica, SiO₂, foil deposited onto a release layer following flame stabilization, and similar foils deposited onto a soot layer without flame densification.

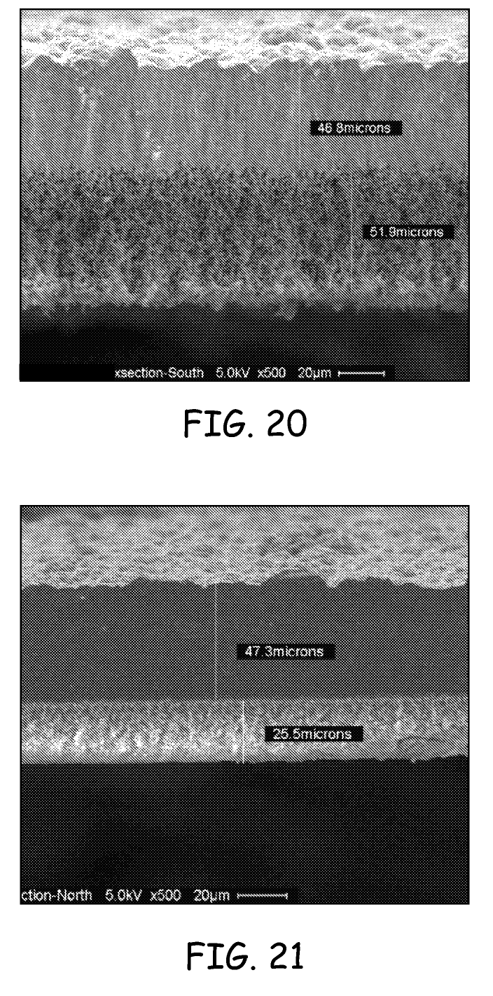

A dense foil or SiO₂ was deposited using SSAP-CVD onto a porous release layer also comprising SiO₂. Referring to FIG. 20, an SEM cross sectional view of a 46.8 micron thick SiO₂ foil is shown on a porous SiO₂ layer deposited by LRD™. The release layer fractured to form a 51.9 micron thick layer from an as deposited approximately 150 micron thick porous layer.

Referring to FIG. 21, an SEM cross sectional view of a 47.3 micron dense layer of SiO₂ is shown on a porous release layer with a thickness of 25.5 microns. The dense layer was deposited with SSAP-CVD. The release layer in FIG. 21 was formed by LRD™ and treated with an oxyacetylene flame to densify the as deposited soot. The dense SiO₂ layer in FIG. 21 has a smoother surface than the corresponding layer in FIG. 20.

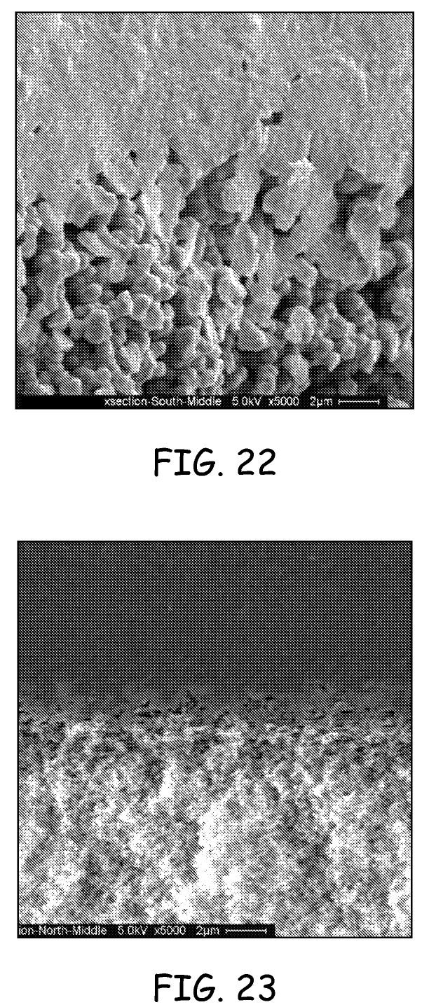

High resolution SEM cross sectional images are shown in FIGS. 22 and 23. The image in FIG. 22 shows a transition region between the layers shown in FIG. 20. The image in FIG. 23 shows a transition region between the layers shown in FIG. 21 in which the release layer was subjected to a flame stabilization prior to deposition of the dense layer. The transition region in FIG. 23 is clearly smaller than the transition region in FIG. 22, with the dense material penetrating significantly further in FIG. 22 than is observed in FIG. 23. The transition region in FIG. 22 has an average thickness of about 10 microns while the transition region in FIG. 23 has an average thickness of about 2 microns. Thus, the flame treatment is observed to result in a smoother top foil surface and in a sharper transition between the release layer and the foil. A smoother transition at the release layer can facilitate removal of remnants of the release layer after separating the foil.

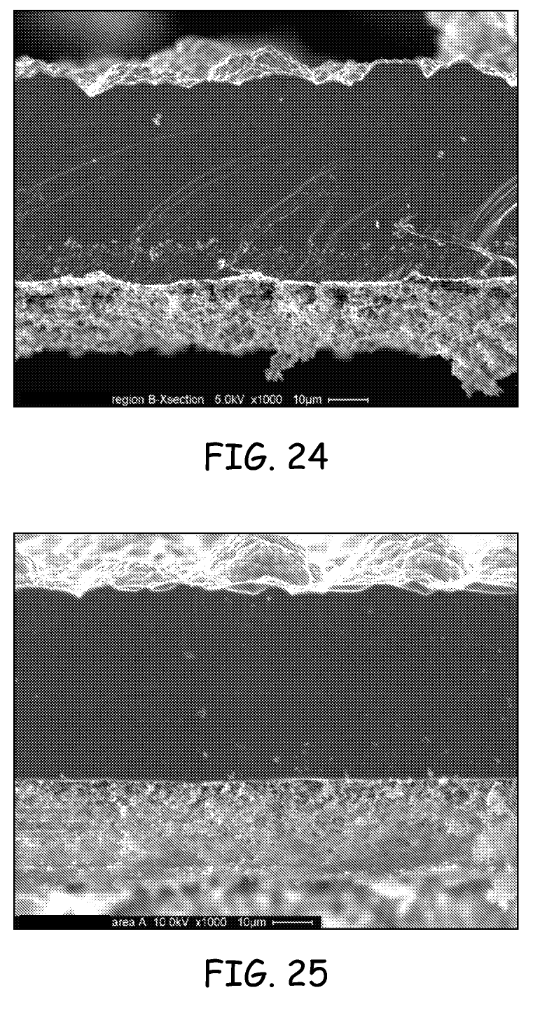

A silicon layer was deposited onto the as deposited SiO₂ porous layer and a porous layer following flame treatment. The silicon foil was then subjected to zone melt recrystallization. An SEM cross sectional image is shown in FIG. 24 for a recrystallized silicon foil on the as deposited porous release layer. In contrast, an SEM cross sectional image is shown in FIG. 25 for a recrystallized silicon foil deposited on a flame treated release layer. By examining the top edge of the foil, the foil on the flame treated release layer has a significantly smoother surface than the foil deposited on the as-deposited release layer. Furthermore, a significantly reduced amount of silicon interpenetrates into the porous release layer. Thus, the silicon foil has significantly improved properties if deposited onto a flame treated release layer.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A method for the deposition of an inorganic foil onto a release layer, the method comprising:
depositing a porous particulate release layer from a product flow generated by a reaction driven by a light beam wherein a reactant flow originates from an inlet and wherein the resulting porous particulate release layer has a density from about 5 percent to about 25 percent of the density of the corresponding fully densified material;
passing a combustion flame over the porous particulate release layer at least once to decrease the average thickness of the porous particulate layer by at least a factor of two relative to the original average thickness of the release layer and to reduce the surface roughness as observed in a scanning electron micrograph; and
depositing an inorganic foil onto the porous particulate release layer after passing the combustion flame over the release layer wherein the inorganic foil has a thickness of no more than about 200 microns and wherein the release layer can be fractured to remove a substantially intact foil.

2. The method of claim 1 wherein the combustion flame is generated from a fuel delivered through the inlet with a combustible flow lacking coating material precursors so that the combustion flame does not result in the deposition of material, and wherein the flame is ignited by the light beam.

3. The method of claim 1 wherein the decrease in the average thickness of the porous layer from the combustion flame is at least a factor of three.

4. The method of claim 1 wherein the inlet opening has an elongated shape characterized by a major axis and a minor axis wherein an aspect ratio of the length of the major axis divided by the length of the minor axis is at lease about 5.

5. The method of claim 1 wherein the release layer comprises an inorganic oxide, an inorganic nitride, an inorganic carbide or a combination thereof.

6. The method of claim 1 wherein the inorganic foil comprises elemental silicon.

7. The method of claim 6 wherein the silicon is doped.

8. The method of claim 1 wherein the foil is deposited by chemical vapor deposition wherein a reactant flow for the chemical vapor deposition is generated from an inlet directed toward a location on the substrate and wherein the substrate and inlet are moved relative to each other to scan deposited material across the substrate.

9. A structure comprising:
an inorganic substrate;
a release layer wherein the release layer comprises an inorganic composition and has an average thickness from about 10 microns to about 200 microns and a density from about 20 percent to about 60 percent of the density of the corresponding fully densified composition and wherein the release layer comprises a porous particulate layer with an interspersed dense inorganic joining composition that has a different chemical composition from the inorganic foil; and
an inorganic foil on the release layer, wherein the inorganic foil comprises a composition with a melting or flow temperature less than the melting or flow temperature of the inorganic composition of the release layer and having a thickness from about 10 microns to about 100 microns.

10. The structure of claim 9 wherein the release layer comprises an inorganic oxide, an inorganic nitride or a combination thereof and wherein the foil comprises doped elemental silicon.

11. A method for the formation of a release layer, the method comprising:
depositing a inorganic composition using chemical vapor deposition onto a porous particulate layer having a thickness from about 10 microns to about 250 microns, wherein the chemical vapor deposition deposits a quantity of inorganic composition corresponding to an equivalent amount of a fully dense composition in a layer with an average thickness from about 0.25 microns to about 10 microns and wherein at least a majority of the composition deposited with chemical vapor deposition is embedded within the porous particulate layer.

12. The method of claim 11 wherein the chemical vapor deposition comprises the delivery of a reactant flow from an inlet directed toward a location on a substrate and wherein the substrate and inlet are moved relative to each other to scan deposited material across the substrate.

13. An apparatus for transferring a thin inorganic foil from a bound position on a substrate to a receiving surface, the apparatus comprising:
a transport element comprising a curved adhering receiving surface;
a substrate support; and
a transport system comprising an actuator and a shifting element, wherein the actuator has a positioning motor that moves the curved receiving surface towards or away from a substrate supported by the substrate support and wherein the shifting element provides a motion to lift an edge of the foil in contact with the receiving surface to propagate a point of contact between the receiving surface and the foil along the respective surfaces.

14. The apparatus of claim 13 wherein the transport element further comprises a receiving body and a support element wherein the receiving body is adhered to the support element and wherein the receiving surface is a surface of the receiving body.

15. The apparatus of claim 14 wherein the receiving surface comprises adhesive that provides the adhering character.

16. The apparatus of claim 14 wherein support element has suction ports that hold the receiving body based on suction.

17. The apparatus of claim 14 wherein the shifting element is configured to rock the receiving surface along a foil on the substrate with contact along a line segment that moves in a linear direction along a fixed substrate as the rocking motion takes place.

18. The apparatus of claim 13 wherein the transport element has a cylindrical receiving surface and wherein the substrate support translates the substrate relative to a point of contact between the receiving surface and the substrate surface to move the substrate approximately an equal amount to the circumferential arc of the rotated portion of the receiving surface.

19. The apparatus of claim 18 further comprising a receiving element transport comprising a receiving element support and a receiving element transport wherein the receiving element transport is configured to contact the cylindrical receiving surface to accept a foil from the cylindrical receiving surface onto a secondary receiving surface on a receiving element hold by the receiving element support.

20. A method for separating an inorganic foil from a substrate wherein the inorganic foil has a thickness of no more than 200 microns, the method comprising:
shifting a curved adhering receiving surface along the surface of the foil to peel the foil from a substrate along a line segment that propagates as the point of contact between the receiving surface and the foil shift along the surface, wherein the foil is initially releaseably bound to the substrate and wherein the foil becomes bound to the receiving surface at least temporarily.

21. The method of claim 20 wherein the curved receiving surface is rocked over a stationary substrate.

22. The method of claim 21 wherein the receiving surface is lowered to contact an edge of the foil prior to initiation of the rocking motion.

23. The method of claim 20 wherein the separation is performed in an enclosure that isolates the interior from the ambient atmosphere.

24. The method of claim 20 wherein the foil comprises doped elemental silicon.

25. The method of claim 20 wherein the foil is crystalline and wherein the curvature of the receiving surface is selected such that the foil is not significantly damaged.
